(19) United States
(12) Patent Application Publication
(10) Pub. No.: US 2026/0011524 A1
(43) Pub. Date: Jan. 8, 2026

(54) MULTI-BEAM PARTICLE MICROSCOPE WITH A QUICKLY REPLACEABLE PARTICLE SOURCE, AND METHOD FOR QUICKLY REPLACING A PARTICLE SOURCE IN THE MULTI-BEAM PARTICLE MICROSCOPE

(71) Applicant: Carl Zeiss MultiSEM GmbH, Oberkochen (DE)

(72) Inventors: Gero STORECK, Aalen (DE); Holger KIEREY, Aalen (DE); Michael KELP, Gerstetten (DE); Andreas ENGELHARDT, Neu-Ulm (DE); Jens MOSCH, Aalen (DE); Alexander WERTZ, Aalen (DE); Christof DIETRICH, Niederstotzingen (DE)

(21) Appl. No.: 19/326,496

(22) Filed: Sep. 11, 2025

Related U.S. Application Data
(63) Continuation of application No. PCT/EP2024/025121, filed on Mar. 22, 2024.

(30) Foreign Application Priority Data
Mar. 29, 2023 (DE) 10 2023 107 961.1

(51) Int. Cl. H01J 37/18; H01J 37/12; H01J 37/14; H01J 37/28

(52) U.S. Cl. CPC H01J 37/18; H01J 37/12; H01J 37/14; H01J 37/28; H01J 2237/2006

(57) ABSTRACT

A multi-beam particle microscope having a quickly replaceable particle source, the microscope comprising a double seal-off and column separation module. Using the double seal-off and column separation module, a replacement module with a particle source can be replaced relatively quickly. Potentially sensitive constituent parts of the particle optics of the multi-beam particle microscope can be protected from contamination.

### CROSS-REFERENCE TO RELATED APPLICATIONS

The present application is a continuation of, and claims benefit under 35 USC 120 to, international application No. PCT/EP2024/025121, filed Mar. 22, 2024, which claims benefit under 35 USC 119 of German Application No. 10 2023 107 961.1, filed Mar. 29, 2023. The entire disclosure of each of these applications is incorporated by reference herein.

### FIELD

The disclosure relates to multi-beam particle microscopes which operate with a multiplicity of charged individual particle beams. For example, the disclosure relates to a multi-beam particle microscope with a quickly replaceable particle source or cathode.

### BACKGROUND

With the ongoing development of ever smaller and ever more complex microstructures such as semiconductor components, there is a general desire to further develop and optimize planar production techniques and inspection systems for producing and inspecting small dimensions of the microstructures. By way of example, the development and production of the semiconductor components can involve monitoring of the design of test wafers, and the planar production techniques can involve process optimization for reliable production with high throughput. Moreover, there have been recent demands for an analysis of semiconductor wafers for reverse engineering and for a customized, individual configuration of semiconductor components. Therefore, there is a general desire for an inspection mechanism which can be used with high throughput to examine the microstructures on wafers with high accuracy.

Typical silicon wafers used in the production of semiconductor components have diameters of up to 300 mm. Each wafer is subdivided into 30 to 60 repeating regions (“dies”) with a size of up to 800 mm². A semiconductor apparatus comprises a plurality of semiconductor structures, which are produced in layers on a surface of the wafer by planar integration techniques. Semiconductor wafers typically have a plane surface on account of the production processes. The structure dimension of the integrated semiconductor structures in this case extends from a few μm to the critical dimensions (CD) of a few nanometres, with the structure dimensions becoming even smaller in the near future; the expectation is that in future the structure dimensions or critical dimensions (CD) will correspond to the 3 nm, 2 nm or even smaller process nodes of the International Technology Roadmap for Semiconductors (ITRS). In the case of the aforementioned small structure dimensions, defects of the order of the critical dimensions are to be identified quickly over a very large area. For several applications, the desired accuracy of a measurement provided by inspection equipment is even higher, for example by a factor of two or one order of magnitude. By way of example, a width of a semiconductor feature is measured with an accuracy of below 1 nm, for example 0.3 nm or even less, and a relative position of semiconductor structures is determined with an overlay accuracy of below 1 nm, for example 0.3 nm or even less.

The MSEM, a multi-beam scanning electron microscope, is a relatively new development in the field of charged particle systems (“charged particle microscopes”, CPMs). By way of example, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a multiplicity of individual electron beams, which are arranged in a field or raster. By way of example, 4 to 10,000 individual electron beams can be provided as primary radiation, with each individual electron beam being separated from an adjacent individual electron beam by a pitch of 1 to 200 micrometres. By way of example, an MSEM has approximately 100 separate individual electron beams (“beamlets”), which are arranged for example in a hexagonal raster, with the individual electron beams being separated by a pitch of approximately 10 μm. The plurality of charged individual particle beams (primary beams) are focused on a surface of a sample to be examined by way of a common objective lens. By way of example, the sample can be a semiconductor wafer which is secured to a wafer holder mounted on a movable stage. When the wafer surface is illuminated by the charged primary individual particle beams, interaction products, for example secondary electrons or backscattered electrons, emanate from the surface of the wafer. Their start points correspond to those locations on the sample onto which the multiplicity of primary individual particle beams are focused in each case. The amount and the energy of the interaction products generally depend on the material composition and the topography of the wafer surface. The interaction products form a plurality of secondary individual particle beams (secondary beams), which are collected by the common objective lens and, by virtue of a projection imaging system of the multi-beam inspection system, are incident on a detector arranged in a detection plane. The detector comprises multiple detection regions, each of which comprises multiple detection pixels, and the detector acquires an intensity distribution for each of the secondary individual particle beams. An image field of 100 μm×100 μm, for example, is obtained in the process.

A known multi-beam electron microscope comprises a sequence of electrostatic and magnetic elements. At least some of the electrostatic and magnetic elements are settable in order to adapt the focus position and the stigmation of the multiplicity of charged individual particle beams. The multi-beam system with charged particles moreover comprises at least one cross-over plane of the primary or the secondary individual charged particle beams. Moreover, the system comprises detection systems in order to facilitate the adjustment. The multi-beam particle microscope comprises at least one beam deflector (“deflection scanner”) for collective scanning of a region of the sample surface via the multiplicity of primary individual particle beams in order to obtain an image field of the sample surface.

As the demands on the imaging quality increase, in general, so do the demands on the multi-beam particle microscope used for imaging. Stable operating parameters are relevant for high-quality recordings. One of these is the beam current intensity of the individual particle beams used to scan a sample surface.

For a uniform beam current intensity of the individual particle beams, the emission characteristic of the particle source is relevant, more precisely the uniformity of the emission characteristic over the entire utilized emission angle. When using relatively large emission angles, the emission characteristic of particle sources, e.g., of thermal field emission (TFE) sources, is generally not uniform throughout. Accordingly, the irradiance at a first multi-aperture plate in a corresponding particle beam system, in general, is not uniform throughout and there can be relatively large variations in the current densities in different individual beams. However, in the case of multi-particle inspection systems, it is generally desirable that only a small variation in the current intensities between the various individual beams, which is typically less than a few percent or even less than one percent, so that all individual image fields of the multi-image field are scanned with an equivalent number of particles or electrons. By way of example, this is a precondition to obtain individual images with approximately the same brightness. The obtainable resolution of the individual images also generally depends on the individual beam current. There are options for setting the beam current on an individual basis for individual particle beams. One option in this respect is disclosed by DE 10 2018 007 652 A1, the disclosure of which is incorporated in this patent application in full by reference.

Further issues with the particle source can arise when a particle source or tip ages; for example, it may lose brightness. The brightness of the images, in turn, generally correlates with the brightness or luminance of the source. If the source loses brightness, this usually also applies to the image brightness. This can be compensated for, at least temporarily, by way of an increased gain at the detection system, even though this may lead to a worse signal-to-noise ratio (SNR) at the detector and leads to a reduction in the obtainable contrast in the images. Another at least temporary approach is to change a voltage applied to an extractor electrode or providing an additional electrostatic control lens between extractor and anode, as proposed in WO 2023/001402 A1, the content of which is incorporated in full in the present patent application by reference. Moreover, it is proposed to estimate a remaining service life of a particle source or cathode tip and optionally to initiate a change in the particle source. Moreover, WO 2023/001401 A1 has disclosed a multi-beam particle microscope enabling highly precise beam current control. The disclosure of WO 2023/001401 A is likewise incorporated in full in the present patent application by reference.

However, in general, the end of the service life of a particle source or cathode tip is inevitably reached at some point, and the particle source is to be replaced. It is known that such a replacement can take several hours or even days, and hence can lead to outage times or downtimes of multi-beam particle microscopes. This can entail relatively long further system downtimes, for example when multi-beam particle microscopes are integrated in production lines, which can be undesirable.

In order to replace a particle source in a multi-beam particle microscope, it is desirable to render the region in which the particle source or cathode tip is situated accessible. A housing present for instance in the upper region is removed. The vacuum or high vacuum in the multi-beam particle microscope is broken. In general, only then can the particle source or cathode tip be replaced by a technician. Subsequently, the multi-beam particle microscope is reassembled. The region provided for evacuation is then pumped out and baked out again. Subsequently, the multi-beam particle microscope with the new or replaced particle source is newly adjusted. The replacement of the particle source typically takes approximately 30 hours, but it may also be drawn out even more.

In addition to the unwanted time outlay, replacing the particle source can mean that the particle optics used in a multi-beam particle microscope are potentially exposed to contamination as a result of the vacuum breaking. The so-called micro-optics as a constituent part of the multi-beam generator are particularly sensitive in this respect. Here, contamination can have a relatively large influence on the beam quality of the individual particle beams generated and should be avoided where possible.

### SUMMARY

The present patent application seeks to provide a multi-beam particle microscope and an associated method, in which a particle source can be replaced quicker. In this case, the replacement of the particle source is desirably as simple as possible and implemented at the best possible time.

The present application seeks to avoid, where possible, a contamination of the multi-beam generator or the micro-optics when replacing the particle source.

A concept discussed in the disclosure is reducing the time outlay for a replacement of the particle source by significantly reducing the time for evacuating the multi-beam particle microscope.

According to embodiments, the volume to be evacuated for a replacement of the particle sources is significantly reduced by appropriately configuring a double seal-off and column separation module. In comparison with the overall system, the interior of the double seal-off and column separation module is the only volume remaining to be evacuated during the replacement itself. In addition, by realizing a module-based replacement of the particle source, it is possible to carry out a prequalification and/or pre-adjustment of the source or its constituent parts relative to one another, and this saves valuable time during the actual replacement of the particle source. Moreover, the double seal-off and column separation module in some embodiment variants can offer sensitive constituent parts of the multi-beam particle microscope, for example the micro-optics, protection against contamination.

According to embodiments, the time outlay for a replacement of the particle source is minimized by virtue of making do completely without the breaking of the vacuum, a renewed evacuation and baking. For example, success in the matter is found by way of a depository solution with a plurality of particle sources or a replacement of particle sources completely in vacuo, or else by way of switching between a plurality of particle sources using electrostatic and/or magnetic deflection mechanisms. Contamination can also be avoided in these solution approaches.

According to a first aspect, the disclosure provides a multi-beam particle microscope with a replaceable particle source, having: a particle source configured to emit charged particles; a multi-beam generator configured to generate a first field of a multiplicity of charged first individual particle beams from the charged particles; a first particle-optical unit with a first particle-optical beam path, configured to image the generated first individual particle beams onto a sample surface in the object plane such that the first individual particle beams are incident on the sample surface at incidence locations, which form a second field; a detection system with a multiplicity of detection regions which form a third field; a second particle-optical unit with a second particle-optical beam path, configured to image second individual particle beams, which emanate from the incidence locations in the second field, onto the third field of the detection regions of the detection system; a magnetic and/or electrostatic objective lens, through which both the first and the second individual particle beams pass;

a beam splitter, which is arranged in the first particle-optical beam path between the multi-beam generator and the objective lens and which is arranged in the second particle-optical beam path between the objective lens and the detection system; a sample stage for holding and/or positioning a sample during a sample inspection; a controller configured to control the multi-beam particle microscope; a beam tube having at least two beam tube portions arranged between the particle source and the beam splitter, wherein the beam tube is evacuated during the operation of the multi-beam particle microscope and wherein the charged particles or the charged first individual particle beams are guided within the beam tube during the operation of the multi-beam particle microscope; and a double seal-off and column separation module which is sealingly arranged between the two beam tube portions during the operation of the multi-beam particle microscope and through which the charged particles or the first individual particle beams pass, and which is spatially separable into a first partial module and into a second partial module when the multi-beam particle microscope is not in operation, wherein the first partial module comprises a first seal-off element configured to sealingly close off the particle source side-adjacent beam tube portion in the case of the spatial separation between the first and second partial module, wherein the second partial module comprises a second seal-off element configured to sealingly close off the beam splitter side-adjacent beam tube portion in the case of the spatial separation between the first and second partial module, and wherein the double seal-off and column separation module comprises an access in an intermediate region between the first seal-off element and the second seal-off element, with the result that the intermediate region is evacuable for the operation of the multi-beam particle microscope and the vacuum in the intermediate region is able to be broken for the purpose of separating the first and the second partial module.

At least one particle source is present, although it is also possible to use multiple particle sources. The charged particles can be, e.g., electrons, positrons, muons or ions or other charged particles. Optionally, the charged particles are electrons generated, e.g., using a thermal field emission source (TFE). However, other particle sources can also be used. The individual field regions of the object (second field) that are assigned to each first individual particle beam can be raster scanned, for example line by line or column by column. In this case, it is possible for the individual field regions to be adjacent to one another or to cover the object or a part thereof in tessellated fashion. The individual field regions can be substantially separate from one another, but they can also overlap one another in the marginal regions. In this way, it is possible to obtain an image of the object that is as complete and contiguous as possible. Optionally, the individual field regions have a rectangular or square form since this is the easiest to realize for the scanning process using particle radiation. Optionally, the individual field regions are arranged as rectangles in different lines one above another in such a way that the overall result is a hexagonal structure. It can be desirable for the number of particle beams to be 3n(n−1)+1, where n is any natural number, in the hexagonal case. Other arrangements of the individual field regions, for example in a square or rectangular raster, are likewise possible.

The second individual particle beams can be backscattered electrons or else secondary electrons. In this case, for analysis purposes it is thus optional for the low-energy secondary electrons to be used to generate the image. However, it is also possible for mirror ions/mirror electrons to be used as second individual particle beams, that is to say first individual particle beams undergoing reversal directly upstream of or at the object.

The beam tube describes that region of the multi-beam particle microscope which is evacuated when the multi-beam particle microscope is in operation. In this context, the beam tube itself can have a single-part or multi-part design. It may comprise tubular portions and/or chamber-like portions. The charged particles or the charged individual particle beams are guided within the beam tube during the operation of the multi-beam particle microscope. For example, the beam tube itself may consist of steel or stainless steel or at least partially of titanium. Certain beam tube portions can be spaced apart from one another and substantially separated from one another by the double seal-off and column separation module. In this case, the double seal-off and column separation module can be sealingly arranged between the two beam tube portions during the operation of the multi-beam particle microscope. Consequently, the double seal-off and column separation module can be designed such that, during the operation of the multi-beam particle microscope, the vacuum prevalent in the beam tube or in the two beam tube portions can be held therein. When the multi-beam particle microscope is not in operation, the double seal-off and column separation module is spatially separable into a first partial module and into a second partial module. This separability is also expressed verbally by the term “column separation module”. Once again, each of the first partial module and the second partial module can have a single-part or multi-part design. It is possible that an intermediate piece, for example an adapter, is provided between the first partial module and the second partial module.

The term “double seal-off module” already indicates verbally that at least two seal-off elements are provided in the double seal-off and column separation module. In this context, the first partial module comprises a first seal-off element and the second partial module comprises a second seal-off element. The first seal-off element is configured to sealingly close off the particle source side-adjacent beam tube portion in the case of the spatial separation between the first and second partial module of the double seal-off and column separation module. The closure itself can be direct or indirect in this context. In this case, the seal-off element can have dimensions corresponding to the diameter of the adjacent beam tube portion. However, it need not reach across the entire width of the first partial module. Analogously, the second seal-off element is configured to sealingly close off the beam splitter side-adjacent beam tube portion in the case of the spatial separation between the first and second partial module of the double seal-off and column separation module. Hence, a disassembly or separation of the double seal-off and column separation module into the first and the second partial module can thus be preceded by in each case attaining a vacuum-tight closure by actuating the first and the second seal-off element, the closure being for the elements or regions of the beam tube situated above and below the double seal-off and column separation module. Consequently, it is not necessary to break the vacuum in these regions and re-evacuate it at a later stage following a replacement of the particle source.

In embodiments, a vacuum is broken, or recreated at a later stage, only within the double seal-off and column separation module. To this end, the double seal-off and column separation module comprises an access in an intermediate region between the first seal-off element and the second seal-off element, with the result that the intermediate region is evacuable for the operation of the multi-beam particle microscope and the vacuum in the intermediate region is able to be broken for the purpose of separating the first and second module. This access can be a single-part or multi-part access. In the case of a simple exemplary embodiment, the access is a drilled hole, connected to which is a line, for example in vacuum-tight fashion, and the line in turn is connected or connectable to a vacuum pump.

According to an embodiment of the disclosure, the multi-beam particle microscope further comprises the following: a replacement module comprising the first partial module of the double seal-off and column separation module and also constituent parts of the multi-beam particle microscope which, in relation to the particle-optical beam path, are arranged above the double seal-off and column separation module, including the particle source. In this case, the replacement module is configured to be replaced as a whole in the multi-beam particle microscope. Thus, it is possible for the replacement module to comprise, as constituent parts, not only the particle source itself but also other elements of the multi-beam particle microscope. In general, this depends on the position of the double seal-off and column separation module in the illumination column or in the particle-optical beam path of the multi-beam particle microscope. In this case, the particle source itself, to be replaced, can in turn be in one part or multiple parts. For example, it may comprise a cathode, an extractor electrode and an anode. Moreover, it may also comprise a suppressor electrode. The arrangement of these elements within the particle source may already be prequalified and/or pre-adjusted in a (new) replacement module. Overall, this can help facilitate the adjustment of the (new) replacement module in relation to the remaining illumination column of the multi-beam particle microscope. The replacement module can comprise all constituent parts of the multi-beam particle microscope which, in relation to the particle-optical beam path, are arranged above the double seal-off and column separation module. In other words, the replacement module in that case comprises the entire “head” of the illumination column.

According to an embodiment of the disclosure, the multi-beam particle microscope further comprises the following: a condenser lens system which is arranged in the particle-optical beam path downstream of the particle source and upstream of the multi-beam generator and through which the charged particles pass, wherein the double seal-off and column separation module is arranged between the condenser lens system and the multi-beam generator. In this case, the condenser lens system can comprise one condenser lens or more condenser lenses. If the double seal-off and column separation module is arranged between the condenser lens system and the multi-beam generator, it is arranged in such a way in this embodiment variant that the charged particles initially pass through all condenser lenses of the condenser lens system before they arrive at the multi-beam generator. Thus, it is the case in this embodiment of the disclosure that the condenser lens system is a constituent part of the replacement module. It is also the case in this embodiment that the double seal-off and column separation module is arranged above the multi-beam generator. Thus, the latter is not also replaced in the process. Instead, when the replacement module including the particle source is replaced, the beam tube portion adjacent on the beam splitter side, which is still upstream of the multi-beam generator in the direction of the particle-optical beam path in this embodiment variant, is sealingly closed off. As a result of this closure, the multi-beam generator and, for example, micro-optics arranged therein are protected against contamination during a particle source replacement.

According to an embodiment of the disclosure, the multi-beam particle microscope comprises the following: a condenser lens system which is arranged in the particle-optical beam path downstream of the particle source and upstream of the multi-beam generator and through which the charged particles pass, wherein the condenser lens system comprises a first for example magnetic condenser lens and a second for example magnetic condenser lens and wherein the double seal-off and column separation module is arranged between the first and the second condenser lens. For example, the double seal-off and column separation module can be arranged within a drift path of the condenser lens system. Overall, this saves installation space or column height. In this embodiment of the disclosure, the replacement module comprises only a part of the condenser lens system, for example at least one for example magnetic condenser lens. Hence, the replacement module is smaller or comprises fewer constituent parts, and this involves fewer resources. Nevertheless, the double seal-off and column separation module is above the multi-beam generator in the particle-optical beam path, with the result that the multi-beam generator can be protected by the sealing second seal-off element of the second partial module of the double seal-off and column separation module when the particle source is replaced.

In general, it is also conceivable to provide the double seal-off and column separation module between the particle source and the condenser lens system. However, this might be refrained from in practice since the particle source and the condenser lens system are usually located relatively close together, and there is usually too little space remaining for an arrangement of the double seal-off and column separation module.

According to an embodiment of the disclosure, the multi-beam particle microscope further comprises the following: a field lens system which is arranged in the particle-optical beam path downstream of the multi-beam generator and upstream of the beam splitter and through which the charged first individual particle beams pass, wherein the field lens system comprises a first for example magnetic field lens and a second for example magnetic field lens, and wherein the double seal-off and column separation module is arranged between the first field lens and the second field lens. However, the field lens system may naturally also comprise more than two field lenses. In this case, the first field lens is considered to be the field lens closest to the multi-beam generator. Thus, the illumination column is separated just below the multi-beam generator or after the first field lens in this embodiment of the disclosure. As a result, the replacement module itself is comparatively large or complex. However, this means that the entire, relatively large replacement module including the particle source and the multi-beam generator, and optionally a condenser lens system situated therebetween, can already be prequalified and/or pre-adjusted before a replacement of the particle source. As a result, the replacement of the particle source within the scope of replacing the replacement module can happen even faster. Moreover, a contamination or dirtying of the multi-beam generator overall is precluded.

According to an embodiment of the disclosure, the double seal-off and separation module is configured to realize an ultrahigh vacuum of 10⁻¹⁰ mbar or better; and/or the double seal-off and separation module is configured to realize a leakage rate of less than or equal to 10⁻⁹ mbar/l/s. As a result, it is possible to maintain the respective high vacuum in the (old or new) replacement module and in the remaining illumination column when separating the first partial module and the second partial module. Moreover, this allows the double seal-off and separation module to be used without problems during the operation of the multi-beam particle microscope; there is no deterioration in the ultrahigh vacuum for the multi-beam particle microscope and the leakage rate does not become too high.

According to an embodiment of the disclosure, the double seal-off and column separation module comprises or consists of a material which is electrically conductive and for the relative permeability μᵣ of which the following applies: μᵣ≤1.005. This relative permeability can be attained by a few stainless steel alloys and also by a few titanium substances. Detailed information regarding the relative permeability of substances used to manufacture beam tube portions are also found in the German patent application with the application number 10 2022 124 933.6, the disclosure of which is incorporated in full in the present patent application by reference. The substances specified therein can also be used as substances for the double seal-off and column separation module.

According to an embodiment of the disclosure, the first and/or second seal-off element of the double seal-off and column separation module comprises an element from the following list: ultrahigh vacuum slider, flap valve, pendulum valve. However, the first and/or second seal-off element may also be designed differently.

According to an embodiment of the disclosure, the first and/or second seal-off element is configured to be operated manually, pneumatically or electrically. In this context, it is possible, for example, to control the first and/or second seal-off element via signals from the controller of the multi-beam particle microscope in the case of non-manual operation. However, the non-manual control can also be implemented independently of the controller of the multi-beam particle microscope.

According to an embodiment of the disclosure, the following relation applies to an overall height h of the double seal-off and column separation module, measured in the installed state along the optical axis of the multi-beam particle microscope: h≤8.0 cm, such as h≤7.0 cm, for example h≤6.0 cm. In this case, the double seal-off and separation module typically has a minimum height h, due to design, of example approx. 5.0 cm, in order to ensure the stability and tightness of the double seal-off and column separation module. At the same time, however, it is desirable to keep this height h as low as possible in order to not unnecessarily increase the overall height of the illumination column, which is significant in any case. In this context, the ceiling height of laboratories is often a limiting aspect. Moreover, the specified overall height h of the double seal-off and column separation module is low enough here in order to house the double seal-off and column separation module for example within a drift path in the illumination column.

For example, such a drift path may be provided within the condenser lens system.

According to an embodiment of the disclosure, the double seal-off and separation module further comprises a heating element arranged within the double seal-off and column separation module. This heating element may accelerate or only even render possible the creation of a high vacuum within the double seal-off and column separation module. The local heating may increase a chamber wall desorption rate, with the result that an ultrahigh vacuum can be achieved more quickly. It is possible that, in the installed state or during the operation of the multi-beam particle microscope, the heating element is controlled via the controller of the multi-beam particle microscope. In this context, the heating element itself can be designed in various ways. For example, it may be designed as a flat heating plate or flat mat; in that case, it can be inserted, for example flatly, into the intermediate space between the first partial module and the second partial module. However, it is also possible for the heating element to have a substantially cylindrical form and/or be wound or slung around one partial module or both partial modules. It is possible that the heating element is made of multiple parts and/or that multiple heating elements are provided, and, for example, a first heating element is arranged in the first partial module and a second heating element is arranged in the second partial module of the double seal-off and column separation module.

According to an embodiment of the disclosure, the double seal-off and column separation module further comprises an adjustment piece for adjusting the replacement module, wherein the adjustment piece is provided adjacent to the first partial module on the particle source side or integrated in the first partial module on the particle source side. The adjustment piece can facilitate a relatively precise adjustment of the (new) replacement module on the remaining illumination column of the multi-beam particle microscope. For example, the adjustment piece may comprise bellows allowing a lateral, axial and/or tilting movement during the fine adjustment of the replacement module on the remaining illumination column. In this case, the adjustment piece may for example be flange-mounted onto the first partial module. However, it is also conceivable that the adjustment piece and bellows are designed integrally with the first partial module.

According to an embodiment of the disclosure, the particle source of the multi-beam particle microscope comprises a cathode tip, an extractor stop and an anode stop, which are arranged flush to one another or which should be arranged flush to one another. Additionally, the particle source may comprise a suppressor electrode which for example surrounds the cathode tip like a cylinder lateral surface and which serves to suppress a lateral emergence of the electrons from the cathode tip. For example, the cathode tip can be a thermal field emitter; however, other configurations are possible in general also. With regards to the aforementioned flush arrangement of cathode tip, extractor stop and anode stop, the cathode tip, the centre of the extractor aperture and the centre of the anode aperture can be exactly in one line or on the optical axis. This exact positioning is generally desirable for highly precise recordings via the multi-beam particle microscope, and this ensures that the particle source or the particles provided thereby are used optimally. Considered spatially, the cathode tip emits a particle cone, wherein the beam current in a cross section through the cone has an approximately plateau-shaped profile over a broad range, before it changes towards the edges of the cone and typically increases in that direction (formation of “teeth”), and then it drops off significantly right at the outside. It is possible to cut off the outer regions of the particle cone beam by way of the extractor stop and/or the anode stop. In other words, charged particles are typically incident at least on a portion of the extractor stop and/or anode stop. This fact can be used for monitoring the cathode tip and/or for adjusting the constituent parts of the particle source. Hence, in this embodiment of the disclosure, the extractor stop can comprise an extractor current meter configured to record a current pattern with spatial resolution around the extractor aperture and/or the anode stop comprises an anode current meter configured to record a current pattern with spatial resolution around the anode aperture. In this context, spatial resolution should be understood to mean that it is not only an overall current that is established. Instead, a positional dependence of the beam current can also be reproduced in the current pattern. In this case, this relates to at least two, but optionally more than two, positions or sectors. The extractor current meter and/or anode current meter can for example comprise mutually insulated sensor plates as current measuring probes which are arranged around the respective aperture and earthed, wherein a current measuring device is connected between the plate and earth. Alternatively, a scintillator on the stops can be used as current meter, and a brightness distribution on the scintillator plate can be established. Thus, the beam current is determined indirectly in this case. Other embodiment variants are also possible.

According to an embodiment of the disclosure, a cathode position adjustment mechanism is provided in order to set a position of the cathode relative to the extractor stop and/or relative to the anode stop on the basis of the recorded current pattern. For example, it is possible to displace the cathode tip in all three spatial directions, to rotate it and/or to tilt it. For example, the cathode tip can be mounted via a hexapod to this end. However, other fine adjustment mechanisms or mounts are also possible.

According to an embodiment of the disclosure, the multi-beam particle microscope further comprises the following: an electrically conductive covering element which, in relation to the particle-optical beam path, is arranged above the multi-beam generator and which is insertable into the particle optical beam path such that the multi-beam generator is covered by the covering element in the inserted state. For example, the electrically conductive covering element can be designed as a metallic slider or metallic cantilever, or as a movable disc. This cover additionally protects the multi-beam generator during a replacement of the particle source. During a replacement of the particle source, the electrically conductive covering element then serves not only to protect against contamination but also to protect electronic components installed in the multi-beam generator against scattered electrons and/or high-energy light radiation.

Moreover, it is possible to provide a multi-beam particle microscope with the described electrically conductive covering element but without the double seal-off and column separation module according to the disclosure.

According to an embodiment of the disclosure, the covering element is designed as a metallic cantilever which is displaceable between a first stop position and a second stop position orthogonally to the particle-optical beam path, wherein the metallic cantilever has a through opening, the diameter of which is matched to a beam tube diameter of the beam tube which is adjacent to the through opening and through which, in the first stop position, the charged particles can pass through the covering element unimpeded, and wherein the metallic cantilever has an for example circular depression, the diameter of which is matched to the beam tube diameter of the adjacent beam tube, and wherein the charged particles are incident in the depression in the second stop position. Thus, for example, the metallic cantilever is a slider which can be moved back and forth between the two stop positions and which introduces the through opening into the particle-optical beam path in one case and the for example circular depression in the other case. In addition to the protective function, this variant can have the further feature that it can be used for beam current measuring purposes, and hence for monitoring purposes and/or adjustment purposes. This is because, according to an embodiment of the disclosure, a beam current meter is arranged in the for example circular depression and/or the circular depression is connected to a beam current meter. For example, this renders it possible to measure scattered electrons. In an alternative or in addition, the direct beam current can also be measured.

According to an embodiment variant, the metallic cantilever has a thickness and extends transversely to the entire beam tube or through the latter. In general, this achieves a lengthening of the beam tube, and it is possible to better protect the multi-beam generator with electronics and/or circuits situated thereon, for example against arising x-ray radiation. The beam current meter is also able to ascertain a beam current directly or indirectly in this embodiment variant. In the case of this embodiment variant, too, it is possible in general to record or monitor the beam current with spatial resolution.

The above-described embodiment variants according to the first aspect of the disclosure can be combined with one another in full or in part, provided that no technical contradictions arise as a result.

According to a second aspect, the disclosure provides a system comprising: a multi-beam particle microscope, as described above in a plurality of embodiment variants, with a replacement module; at least one further replacement module for the multi-beam particle microscope; a depository having at least one vacuum-tight connector for the at least one further replacement module, wherein the depository is configured to store the interior of the further replacement module in the depository in a high vacuum, for example in an ultrahigh vacuum, when the first seal-off element of the further replacement module is open. In this case, the replacement module and the further replacement module can be structurally identical. Before the at least one further replacement module is brought into the depository, the replacement module can be prequalified and/or pre-adjusted. This can save significant amounts of time when changing the particle source in the multi-beam particle microscope. Moreover, in the case of the depository, it is possible to already evacuate and/or bake the at least one further replacement module and thus reduce the evacuation and baking time, which is significant during a change in the particle source, or carry this out before the actual replacement of the particle source. The at least one vacuum-tight connector in the depository can be dimensioned such that the replacement module or the first partial module of the double seal-off and column separation module can be connected thereto in vacuum-tight fashion. The depository-side connector can have dimensions and tightness properties that are identical to the second partial module of the double seal-off and column separation module, which remains on the remaining column of the illumination column when the particle source is replaced. However, it may also have a different embodiment provided the corresponding connection option and the desired sealing properties are present.

According to a third aspect, the disclosure provides a method for replacing a particle source in a multi-beam particle microscope as described above in various embodiments. In this case, the multi-beam particle microscope comprises a replacement module as described above and the method includes the following steps: closing the first seal-off element and the second seal-off element of the double seal-off and column separation module; breaking the vacuum in the double seal-off and column separation module in a region between the first seal-off element and the second seal-off element; spatially separating the double seal-off and column separation module into the first partial module and into the second partial module and thereby separating the first replacement module including the first particle source from the remaining part or from the remaining illumination column of the multi-beam particle microscope; arranging a second replacement module including a second particle source on the remaining part of the multi-beam particle microscope or on the remaining illumination column and thereby putting together a second double seal-off and column separation module, wherein the second replacement module is already evacuated and wherein the first seal-off element thereof is closed; evacuating the second double seal-off and column separation module in the region between its first seal-off element and its second seal-off element; opening the first seal-off element of the second double seal-off and column separation module and the second seal-off element of the second double seal-off and column separation module after the evacuation has taken place.

The terms used here in the context of a method according to the disclosure are the same as those which have also already been used and defined above in the context of the multi-beam particle microscope or in the context of the system. The described method describes in detail the replacement of a first replacement module with a first particle source for a second replacement module with a second particle source using the double seal-off and column separation module. The double seal-off and column separation module is spatially separable into the first partial module and into the second partial module. Within the scope of the method, as described above, the double seal-off and column separation module can be reassembled as it were: the second partial module remains identical while the first partial module—as it is considered part of the replacement module—is replaced. Thus, the first double seal-off and column separation module is the double seal-off and column separation module originally present, and the second double seal-off and column separation module is the newly assembled double seal-off and column separation module. A corresponding statement applies to a possible third replacement module with a third particle source and a third double seal-off and column separation module assembled or assemblable thus.

According to an embodiment variant, the method moreover includes heating the first and/or second double seal-off and column separation module. This heating can be implemented in the case of a double seal-off and column separation module that has been installed into the multi-beam particle microscope, and the heating may also be maintained during the normal operation of the multi-beam particle microscope. In addition or in an alternative, it is also possible to heat a proportion of the double seal-off and column separation module located in a depository in order to be able to evacuate the entire replacement module in the depository faster and/or more sustainably. To this end, the first seal-off element is opened in the depository.

According to an embodiment variant, the method moreover includes the following step: pre-adjusting or technically prequalifying the second replacement module before the second replacement module is arranged on the remaining part of the multi-beam particle microscope. This can be a feature of the method according to the disclosure or the multi-beam particle microscope according to the disclosure: the pre-adjustment and/or technical prequalification allows valuable time to be saved during a replacement of the particle source. The technical prequalification and/or pre-adjustment may contain the establishment of the ultrahigh vacuum (pumping-off with baking), the running-in of the tip cathode (high-voltage conditioning), the characterizing of the emission characteristic of the tip cathode and the adjustment of the electron beam to bring it in line with the optical axis.

According to an embodiment of the disclosure, the method moreover includes the following step: storing the second replacement module in an evacuated state in a depository. As a result, the second replacement module is ready to use very quickly or can be replaced with the first replacement module. For example, the depository itself can be located in the same room as the multi-beam particle microscope; however, it may also be located in an adjacent room or at least in the same building. The shorter the paths between the depository and the multi-beam particle microscope, in general, the faster the progress of the overall replacement process for the particle source. Moreover, possible losses in adjustment during transport of the second replacement module to the multi-beam particle microscope can be avoided. However, it is naturally also possible for the depository to be at a remote location in comparison with the multi-beam particle microscope. In this case, storage itself may be implemented over relatively long periods of time, for example over a few months or a few years. In the process, the vacuum in the stored replacement module is optionally maintained throughout; the first seal-off element can remain open throughout.

According to an embodiment of the disclosure, the method moreover includes the following steps: isostatically arranging the second replacement module on the remaining part of the multi-beam particle microscope or the illumination column; and/or adjusting the second replacement module via an adjustment piece; and/or adjusting the second replacement module via electric and/or magnetic deflection fields which deflect the charged particles and/or the charged first individual particle beams. In this context, isostatically arranging the second replacement module against or on the remaining part of the multi-beam particle microscope without having to carry out further adjustment processes represents the ideal case.

The adjustment of the second replacement module via an adjustment piece describes a mechanical adjustment or an adjustment with mechanical mechanism, wherein for example the second replacement module can be displaced, rotated and/or tilted in comparison with the remaining part of the multi-beam particle microscope. If the second replacement module is adjusted via electric and/or magnetic deflection fields, it is possible for an additional mechanical adjustment to be able to be dispensed with. However, the latter might also additionally be present. An example of an adjustment of the second replacement module via electric and magnetic deflection fields is, for example, modified control of one or more condenser lenses and/or of electric and/or magnetic deflectors or double deflectors provided in the condenser lens system. It is also possible that one or more further electric and/or magnetic deflectors are provided for adjustment purposes.

According to an embodiment of the disclosure, the method moreover includes the following steps: monitoring a current pattern in the region of the particle source; and adjusting constituent parts of the particle source relative to one another on the basis of the current pattern.

For example, the constituent parts of the particle source can be a cathode tip, an extractor stop and an anode stop, which should be aligned flush with one another. In this context, monitoring of a current pattern in the region of the particle source can be implemented on the extractor stop and/or on the anode stop, for example. For example, the current pattern can be recorded with spatial resolution. In that case, the current pattern can be used particularly well for adjustment purposes.

According to an embodiment of the disclosure, the method moreover includes the following steps: monitoring a current pattern in the region of the particle source; and predicting a remaining service life of the particle source and, for example, initiating a replacement of the particle source, in each case on the basis of the current pattern. In general, it is known that the emission characteristic of a particle source changes over the course of the service life of a particle source, and how it typically changes. Thus, a change in the particle source can be observed by monitoring a current pattern during the operation of the multi-beam particle microscope. From this, it is possible to predict the remaining service life of the particle source and, for example, also initiate the replacement of the particle source in timely fashion.

In an alternative or in addition, it is also possible to derive the remaining service life of the particle source from other current measurements. Indications in this respect can also be derived from a beam current measurement, for example on a first multi-aperture plate of the multi-beam generator. Detailed information in this respect can be gathered from WO 2023/001402 A1, already cited at the outset, the disclosure of which is incorporated in full in the present patent application by reference.

According to an embodiment of the disclosure, the method is carried out multiple times in full or in part, wherein for example a third replacement module with a third particle source and/or a further replacement module with a further particle source is arranged on the remaining part of the multi-beam particle microscope or on the remaining illumination column. For example, the method can be carried out until all replacement modules stored in a depository have in fact been installed in the multi-beam particle microscope. Moreover, it is naturally also possible to fill the depository with further replacement modules in the meantime and hence in general carry out the method according to the disclosure for any desired length of time.

According to a fourth aspect, the disclosure provides a multi-beam particle microscope with a replaceable particle source, having: a first vacuum region having a first particle source arranged in an operational position and configured to emit charged particles; a multi-beam generator configured to generate a first field of a multiplicity of charged first individual particle beams from the charged particles; a first particle-optical unit with a first particle-optical beam path, configured to image the generated first individual particle beams onto a sample surface in the object plane such that the first individual particle beams are incident on the sample surface at incidence locations, which form a second field; a detection system with a multiplicity of detection regions which form a third field; a second particle-optical unit with a second particle-optical beam path, configured to image second individual particle beams, which emanate from the incidence locations in the second field, onto the third field of the detection regions of the detection system; a magnetic and/or electrostatic objective lens, through which both the first and the second individual particle beams pass; a beam splitter, which is arranged in the first particle-optical beam path between the multi-beam generator and the objective lens and which is arranged in the second particle-optical beam path between the objective lens and the detection system; a sample stage for holding and/or positioning a sample during a sample inspection; a controller configured to control the multi-beam particle microscope; a second vacuum region having a storage unit which comprises at least one second particle source of the identical construction as the first particle source as replacement particle source; and a transfer mechanism for a vacuum transfer of the second particle source from the storage unit of the second vacuum region into the operational position in the first vacuum region.

In this context, operational position is understood to mean the position of a particle source in the multi-beam particle microscope in which a particle source is arranged during the operation of the multi-beam particle microscope. In this embodiment of the disclosure, the operational position is not a storage position, in which a particle source is only stored. Thus, the operational position differs from a storage position in this embodiment of the disclosure. By contrast, one or more such storage positions are found in the storage unit.

According to this embodiment of the disclosure, the active particle source, i.e. the particle source in operation or currently provided for operation, is in a vacuum region. Consequently, the operational position is located in a vacuum region, for example the first vacuum region. Likewise, the storage unit with the at least second particle source as replacement particle source is also located in a vacuum, for example in the second vacuum region. Consequently, storage positions are located in a vacuum region. In this context, it is possible that the first vacuum region and the second vacuum region are formed as two vacuum chambers which are separated from one another. For example, it is possible that they are separated from one another by an airlock. However, it is also possible that the first vacuum region and the second vacuum region are arranged in the same vacuum chamber, i.e. without interposed airlock(s). It is also possible that the second vacuum region is composed of a plurality of vacuum chambers. The effect can be the same: the replacement of a particle source can be implemented completely in vacuo in this embodiment variant of the disclosure. Therefore, it is possible to make do without a possible evacuation of vacuum chambers and a desirable baking of vacuum chambers, etc. It is therefore possible to replace a particle source much quicker.

In this embodiment of the disclosure, the transfer mechanism can be configured for a vacuum transfer of the second particle source from the storage unit of the second vacuum region into the operational position in the first vacuum region. In this context, it is optionally also possible that the transfer mechanism is further configured for a vacuum transfer of the first particle source from the operational position in the first vacuum region into the storage unit of the second vacuum region. Hence, it is possible to not only bring the replacement particle source into the operational position but also remove the old particle source from the operational position completely in vacuo. In this context, the transfer mechanism itself can have a single part or multi-part design. For example, a transfer rod or a plurality of transfer rods can be used for the transfer under vacuum conditions. For example, the actuation of a transfer rod can be implemented manually or in automated fashion by way of a suitable motor and/or sensor system. Moreover, the transfer mechanism may comprise mechanical positioning mechanisms such as guides, positioning pins, screws or clamps.

The particle source itself may comprise a unit made of a plurality of constituent parts, for example the cathode tip, an extractor stop and an anode stop. It can also concomitantly comprise a suppressor electrode. However, it may also consist only of a cathode tip. In this embodiment according to the fourth aspect of the disclosure, the replacement particle source as a unit can be smaller than the replacement module according to the first aspect of the disclosure. This is because, since the replacement particle source is already in the vacuum, there is no compulsion to at the same time also replace a housing part which contains the particle source and which maintains the vacuum around the particle source. Moreover, it is desirable within the scope of this embodiment variant to keep the storage space for the replacement particle source(s) as small as possible in order to be able to house as many replacement particle sources as possible in the storage unit. Nevertheless, this can relate to a preconfigured replacement unit with a plurality of constituent parts such as, for example, cathode tip, extractor stop and anode stop, and optionally suppressor electrode, because it is possible in that case to already preconfigure these constituent parts of the replacement particle source prior to the actual replacement of the particle source in vacuo. In other words, the storage unit contains only already prequalified and/or pre-adjusted replacement particle sources as a future replacement particle source(s). This can facilitate the subsequent exact positioning and adjustment of the replacement particle source in the operational position following a particle source replacement, and this in turn saves time.

According to an embodiment of the disclosure, the storage unit comprises a plurality of storage positions or storage spaces for the replacement particle sources which are arranged according to a physically linear topology. For example, a storage bus system which for example is displaceable over a stage for example in the Z-direction can be used as a storage unit in this embodiment variant. It is also conceivable to use transfer rods for a movement of the storage bus system. In any case, what holds true in this embodiment variant is that, by way of an appropriate movement mechanism, the replacement particle sources can be brought via a linear movement into their initial position for the subsequent transfer from the second vacuum region into the first vacuum region.

According to an alternative embodiment of the disclosure, the storage unit has a plurality of storage positions or storage spaces for the replacement particle sources which are arranged according to a physically stellate topology. Thus, what holds true in this embodiment variant is that the storage positions are for example arranged annularly, wherein the replacement particle sources can then be brought into the centre of the ring for the transfer into the operational position. Expressed differently, the operational position for the respectively active particle source is centrally midway between the storage positions of the storage unit. Since the replacement particle sources are in each case brought into the centre of the topology, reference in this context is also made to a stellate topology and not for instance to a ring-shaped topology. For example, the transfer mechanism itself may comprise a plurality of transfer rods in this embodiment variant, with this plurality optionally corresponding to the number of storage positions. In other words, what holds true is that a respective transfer rod is used for transport from a storage position to the operational position. In this embodiment variant, the operational position itself is accessible from different directions.

According to an alternative embodiment of the disclosure, the storage unit has a plurality of storage positions or storage spaces for the replacement particle sources which are arranged according to a physically ring-shaped topology. In this embodiment, the replacement particle sources are moved along a ring for the purpose of a particle source replacement. The operational position is situated on this ring in this case. This topology may be realized, for example, by a turret mechanism, e.g. a rotating stage with replacement particle sources in the high vacuum.

According to an embodiment of the disclosure, the multi-beam particle microscope further comprises the following: a contacting unit for electrical contacting of the respectively active particle source in the operational position; and an adjustment unit for fine positioning of the respectively active particle source in the operational position. In this case, the contacting unit can have a single or multi-part design. The electrical contacting may comprise one or more contacting sites. For example, it is possible to provide separate contacting for each electrode of the particle source. It is possible that this contacting unit is movable relative to the operational position, for example via a stage which is for example displaceable in one direction. For example, a connector with a plurality of electrical contacts can be realized in this way and the replacement particle source can be accordingly connected. In general, electrical contacting can be established within the vacuum via connectors, clamp and/or sliding contact.

The adjustment unit for a fine positioning of the respectively active particle source in the operational position can, in this case too, have a single or multi-part design once again. It can be realized in different ways, for example by way of a 3-D stage and/or by way of piezoelectric elements. Other embodiments are also possible.

According to an embodiment of the disclosure, each replacement particle source comprises a tip cathode, an extractor electrode and an anode, which are already adjusted and/or technically prequalified relative to one another. Consequently, it is possible to largely or completely make do without fine adjustments of the constituent parts of the replacement particle source relative to one another in this embodiment variant, and this saves time.

According to a fifth aspect, the disclosure provides a multi-beam particle microscope with a replaceable particle source, having: a plurality of identically constructed particle sources arranged fixedly in space, each configured to emit charged particles; a switching mechanism configured to switch between the particle sources such that at any one time only in each case exactly one of the particle sources is an active particle source which emits charged particles; an electric and/or magnetic deflection mechanism configured to deflect the charged particles emitted by the respectively active particle source onto the optical axis of the multi-beam particle microscope; a multi-beam generator configured to generate a first field of a multiplicity of charged first individual particle beams from the charged particles from a particle source; a first particle-optical unit with a first particle-optical beam path, configured to image the generated first individual particle beams onto a sample surface in the object plane such that the first individual particle beams are incident on the sample surface at incidence locations, which form a second field; a detection system with a multiplicity of detection regions which form a third field; a second particle-optical unit with a second particle-optical beam path, configured to image second individual particle beams, which emanate from the incidence locations in the second field, onto the third field of the detection regions of the detection system; a magnetic and/or electrostatic objective lens, through which both the first and the second individual particle beams pass; a beam splitter, which is arranged in the first particle-optical beam path between the multi-beam generator and the objective lens and which is arranged in the second particle-optical beam path between the objective lens and the detection system; a sample stage for holding and/or positioning a sample during a sample inspection; a controller configured to control the particle sources, the switching mechanism and the deflection mechanism. Naturally, it is also possible that the controller controls the multi-beam particle microscope overall. In general, the controller itself can have a single-part or multi-part design.

This embodiment of the disclosure can make do without a transfer mechanism for transferring the particle sources. Instead, the active particle source and the replacement particle sources are already arranged fixed in space in the multi-beam particle microscope (under vacuum). Thus, there is a switchover between the particle sources rather than a mechanical transfer in this embodiment variant. In general, this embodiment variant thus includes a plurality of mutually different operational positions, which are also storage positions intermittently. So that the emitted charged particles can be coupled precisely into the illumination column of the multi-beam particle microscope from each of these operational positions, provision is made for an electric and/or magnetic deflection mechanism. In this context, the deflection mechanism can have a single-part or multi-part design. This embodiment variant of the disclosure also allows a fast replacement or change of the particle source since the replacement of the particle source does not require a breaking of the vacuum, does not require a renewed evacuation of the multi-beam particle microscope and also does not require renewed baking. Moreover, the spatially fixed arrangement of the particle sources also makes it possible within the scope of the particle source replacement to make do without fine adjustments of the particle sources themselves. Instead, each particle source can be adjusted independently during an initial adjustment of the multi-beam particle microscope. Naturally, it is of course nevertheless possible to provide one or more further mechanisms for a subsequent fine adjustment, as has already been described in the context of the other embodiment variants of the disclosure.

The switching mechanism for switching between the particle sources can be a selection button or a selection display, for example. However, it is also possible for the switching mechanism to be provided or integrated implicitly in the controller of the multi-beam particle microscope. For example, it is possible for an automatic switchover to occur precisely when the replacement of the particle sources appears desirable.

According to an embodiment of the disclosure, the multi-beam particle microscope comprises exactly four particle sources which are arranged opposite one another in pairs and which are moreover arranged such that each of the particle sources can emit charged particles orthogonally to the optical axis of the multi-beam particle microscope. In other words, what holds true is that an emission of the charged particles from the particle sources is implemented not directly from above in the direction of the optical axis of the multi-beam particle microscope, but at 90° to the optical axis, that is to say to the side. In this embodiment variant of the disclosure, the switching mechanism comprises two pairs of Helmholtz coils and hence four coils overall, wherein only one pair of the Helmholtz coils is in each case active at any one time. Moreover, a respective coil is arranged between one of the particle sources and an imaginary extension of the optical axis of the multi-beam particle microscope. Thus, in this context, the sequence particle source-coil of the Helmholtz coil pair-imaginary extension of the optical axis of the multi-beam particle microscope is realized four times in each case. The axes of the Helmholtz coil pairs themselves are arranged orthogonal to the optical axis of the multi-beam particle microscope (or its imaginary extension) such that a magnetic field respectively generable by a Helmholtz coil pair is oriented orthogonal to the optical axis of the multi-beam particle microscope. Moreover, the controller is configured to control the Helmholtz coil pairs in such a way that the charged particles emitted by the respectively active particle source are deflected or redirected in the direction of the optical axis of the multi-beam particle microscope.

In this embodiment of the disclosure, the particle source can comprise a cathode tip, an extractor stop and an anode stop, and optionally a suppressor electrode.

According to an alternative embodiment of the disclosure, the multi-beam particle microscope comprises exactly four particle sources which are arranged opposite one another in pairs and in each case arranged tilted through an angle α≠0°, for example 40°≤α≤50°, such as α=45°, with respect to the optical axis of the multi-beam particle microscope. In comparison with the above-described embodiment variant with the two pairs of Helmholtz coils, the four particle sources thus are tilted in the direction of the optical axis of the multi-beam particle microscope. In this embodiment of the disclosure, the deflection mechanism comprises four deflection electrodes, each assigned to a particle source. The deflection electrodes can be identical to the four anodes of the four particle sources; however, separate deflection electrodes may also be provided. For example, the deflection electrodes can be configured as deflection electrode stops. For example, these electrode stops can be arranged parallel to the anode stops or extractor stops of the particle sources. In this embodiment variant of the disclosure, the controller can be likewise configured to use a deflection potential to control the deflection electrode of the particle source in each case opposite the active particle source, in such a way that the charged particles emitted by the respectively active particle source are deflected or redirected in the direction of the optical axis of the multi-beam particle microscope. Moreover, it is possible to apply a voltage for an adjustment in a transverse direction to the other two deflection electrodes, which are not assigned to the active particle source and also not assigned to the particle source exactly directly opposite the active particle source. Thus, this embodiment of the disclosure also can make do completely without a transfer of the particle sources. Ideally, there is also no need for mechanical adjustment within the scope of the replacement of the particle source. Instead, electric fields are used for the switchover and optional (fine) adjustment. Hence, this replacement of the particle source is likewise implementable very quickly and moreover very precisely.

The above-described embodiments of the disclosure within one aspect of the disclosure and in aspect-overarching manner can be combined with one another in full or in part, provided that no technical contradictions arise as a result.

### BRIEF DESCRIPTION OF THE DRAWINGS

The disclosure is with reference to the accompanying figures, in which:

FIG. 1: schematically shows a multi-beam particle microscope;

FIG. 2: schematically shows a sectional view of a double seal-off and column separation module;

FIGS. 3A-3B: schematically show a spatial representation of a double seal-off and column separation module;

FIGS. 4A-4B: schematically show an illumination column of a multi-beam particle microscope and double seal-off and column separation module;

FIGS. 5A-5C: schematically show various arrangements of a double seal-off and column separation module in a multi-beam particle microscope;

FIGS. 6A-6C: schematically illustrate replacement of a particle source;

FIG. 7: schematically shows a portion of a multi-beam particle microscope with a replaceable particle source, wherein replacement particle sources are arranged in a storage unit;

FIG. 8: schematically shows a portion of a multi-beam particle microscope with a replaceable particle source, wherein replacement particle sources are arranged in a storage unit;

FIGS. 9A-9B: schematically show a portion of a multi-beam particle microscope with a replaceable particle source, wherein replacement particle sources are arranged in a storage unit;

FIGS. 10A-10B: schematically show a portion of a multi-beam particle microscope with a replaceable particle source, wherein the replacement is implemented by way of a switchover;

FIGS. 11A-11B: schematically show a portion of a multi-beam particle microscope with a replaceable particle source, wherein the replacement is implemented by way of a switchover;

FIG. 12: schematically shows a portion of a multi-beam particle microscope with a replaceable particle source, wherein the replacement is implemented by way of a switchover;

FIGS. 13A-13B: schematically shows a multi-beam particle source and a position dependence of its current intensity;

FIGS. 14A-14B: schematically show a current pattern acquisition at an anode stop, which can be used to finely adjust the particle source;

FIG. 15: schematically shows a plan view of a covering element that is insertable into the beam path;

FIG. 16: schematically shows a sectional representation of a covering element that is insertable into the beam path;

FIG. 17: schematically shows a sectional view of a double seal-off and column separation module with a fill volume;

FIGS. 18A-18B: schematically show a foldable shielding element for a seal;

FIGS. 19A-19B: schematically show a spatial representation of a double seal-off and column separation module with a foldable shielding element for a seal; and

FIG. 20: schematically shows differential pumping in the case of a double seal-off and column separation module.

### DETAILED DESCRIPTION

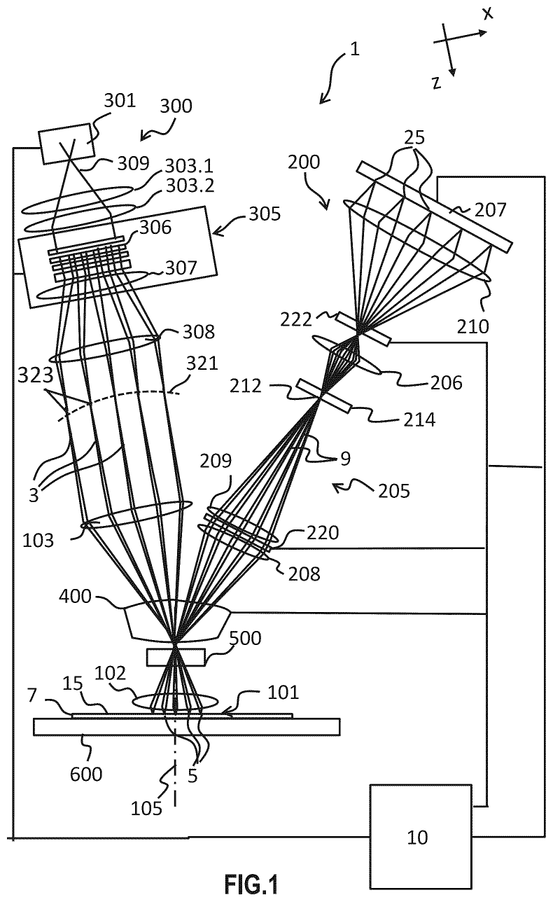

FIG. 1 schematically shows a multi-beam particle microscope 1. The multi-beam particle microscope 1 comprises a beam generating apparatus 300 with a particle source 301, for example an electron source. A divergent particle beam 309 is collimated by a sequence of condenser lenses 303.1 and 303.2 and impinges on a multi-aperture arrangement 305. The multi-aperture arrangement 305 comprises a plurality of multi-aperture plates 306 and a field lens 308. A multiplicity of individual particle beams 3 or individual electron beams 3 is generated by the multi-aperture arrangement. Midpoints of apertures in the multi-aperture plate arrangement are arranged in a field which is imaged onto a further field formed by beam spots 5 in the object plane 101. The distance between the midpoints of apertures of a multi-aperture plate 306 can be 5 μm, 100 μm and 200 μm, for example. The diameters D of the apertures are smaller than the pitch of the midpoints of the apertures; examples of the diameters are 0.2 times, 0.4 times and 0.8 times the distances between the midpoints of the apertures.

The multi-aperture arrangement 305 and the field lens 308 are configured to generate a multiplicity of focal points 323 of primary beams 3 in a raster arrangement on a surface 321. The surface 321 need not be a plane surface but rather can be a spherically curved surface in order to account for an image field curvature of the subsequent particle-optical system.

The multi-beam particle microscope 1 further comprises a system of electromagnetic lenses 103 and an objective lens 102, which image the beam foci 323 from the intermediate image surface 325 into the object plane 101 with reduced size. In between, the first individual particle beams 3 pass through the beam splitter 400 and a collective beam deflection system 500, via which the multiplicity of first individual particle beams 3 are deflected during operation and the image field is scanned. The first individual particle beams 3 incident in the object plane 101 for example form a substantially regular field, wherein distances between adjacent incidence locations 5 can be 1 μm, 10 μm or 40 μm, for example. By way of example, the field formed by the incidence locations 5 can have a rectangular or hexagonal symmetry.

The object 7 to be examined can be of any desired type, for example a semiconductor wafer or a biological sample, and can comprise an arrangement of miniaturized elements or the like. The surface 15 of the object 7 is arranged in the object plane 101 of the objective lens 102. The objective lens 102 can comprise one or more electron-optical lenses. For example, this can be a magnetic objective lens and/or an electrostatic objective lens.

The primary particles 3 incident on the object 7 generate interaction products, for example secondary electrons, backscattered electrons or primary particles which have experienced a reversal of movement for other reasons, and these interaction products emanate from the surface of the object 7 or from the first plane 101 or object plane 101. The interaction products emanating from the surface 15 of the object 7 are shaped by the objective lens 102 to form secondary particle beams 9. In the process, the secondary beams 9 pass through the beam splitter 400 downstream of the objective lens 102 and are supplied to a projection system 200. The projection system 200 comprises an imaging system 205 with projection lenses 208, 209 and 210, a contrast stop 214 and a multi-particle detector 207. Incidence locations 25 of the second individual particle beams 9 on detection regions of the multi-particle detector 207 are located with a regular pitch in a third field. Exemplary values are 10 μm, 100 μm and 200 μm.

The multi-beam particle microscope 1 further comprises a computer system or a control unit 10, which in turn can have a single-part or multi-part design and which is designed both to control the individual particle-optical components of the multi-beam particle microscope 1 and to evaluate and analyse the signals obtained by the multi-detector 207 or the detection unit.

Further information relating to such multi-beam particle beam systems or multi-beam particle microscopes 1 and components used therein, such as, for instance, particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which is incorporated in full in the present application by reference.

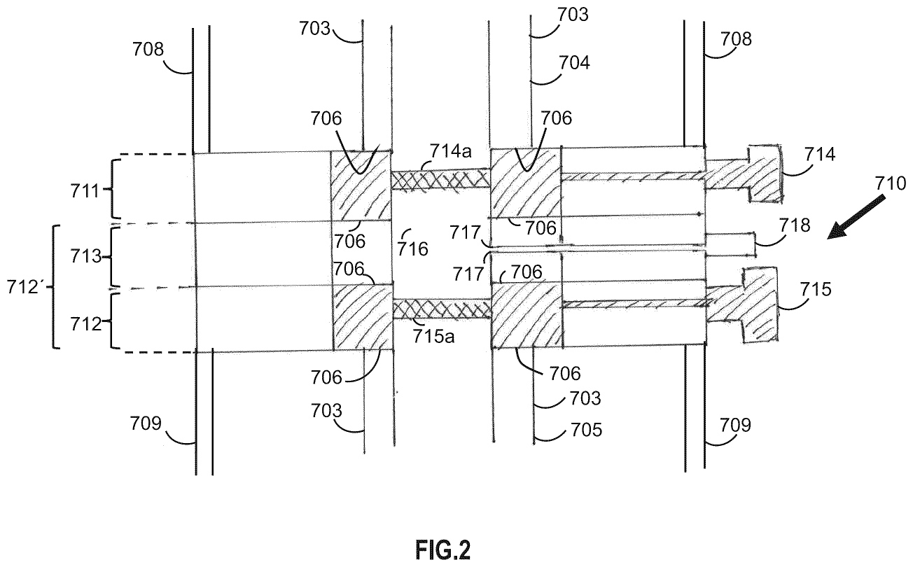

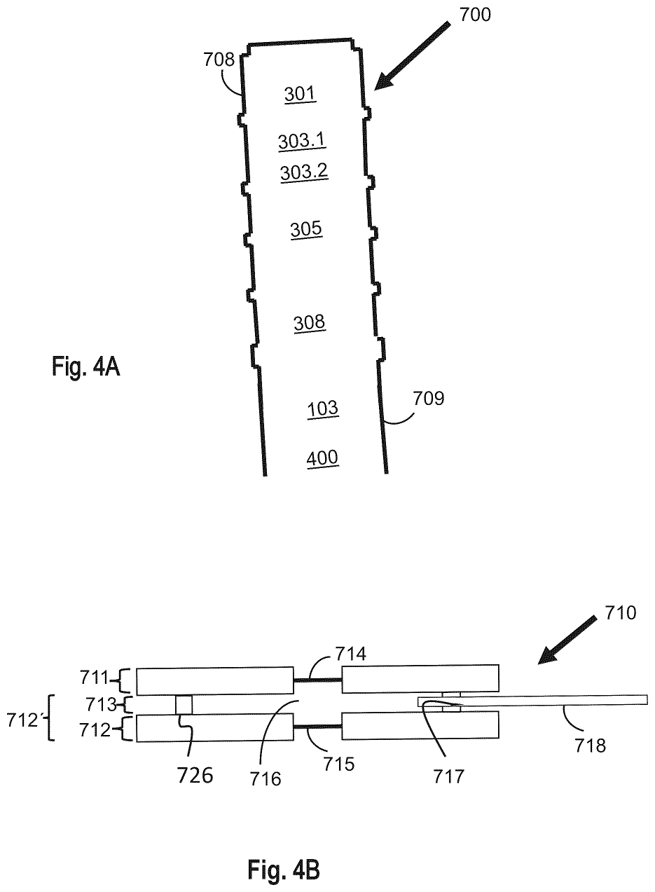

FIG. 2 schematically shows a sectional view of a double seal-off and column separation module 710, which may be integrated in the multi-beam particle microscope depicted in FIG. 1. The double seal-off and column separation module 710 is arranged in the illumination column of the multi-beam particle microscope 1. In this case, FIG. 2 shows only a portion of the illumination column. A housing 708 with a first beam tube portion 704 and a housing 709 with a second beam tube portion 705 are shown. The beam tube 703 is subdivided into the two beam tube portions 704, 705 by the double seal-off and column separation module 710. During the operation of the multi-beam particle microscope 1, or in the installed state, the double seal-off and column separation module 710 is sealingly arranged between the two beam tube portions 704, 705, and the charged particles or the first individual particle beams 3 (the charged particles and the first individual particle beams 3 are not depicted explicitly in FIG. 2) pass through the double seal-off and column separation module. Sealing surfaces 706 for the sealing arrangement are depicted by way of example in FIG. 2. In this case, the aim is to ensure the high vacuum for the operation of the multi-beam particle microscope even in the installed double seal-off and column separation module 710. When the multi-beam particle microscope 1 is not in operation, the double seal-off and column separation module 710 is spatially separable into a first partial module 711 and into a second partial module 712. To this end, the double seal-off and column separation module 710 is suitably accessible from the outside, with the result that the first partial module 711 and the second partial module 712 are spatially separable, for example by unscrewing screw connections. It is possible that an intermediate piece or adapter 713 is arranged between the first partial module 711 and the second partial module 712. However, it is also possible that this adapter 713 belongs to the second partial module 712, which is indicated in FIG. 2 by reference sign 712′ (cf. also FIG. 4B). The first partial module 711 comprises a first seal-off element 714 configured to sealingly close off the particle source side-adjacent beam tube portion 704 in the case of the spatial separation between the first and second partial module 711, 712. The second partial module 712 comprises a second seal-off element 715 configured to sealingly close off the beam splitter side-adjacent beam tube portion 705 in the case of the spatial separation between the first and second partial module 711, 712. The seal-off elements 714, 715 are depicted in a closure position in FIG. 2. As a result, the beam tube 703 is in each case sealed vacuum-tightly by a constituent part of the seal-off elements 714, 715. The seal-off elements in the narrower sense are depicted with reference signs 714a and 715a in FIG. 2. In this case, the seal-off elements 714, 715 can be realized in different ways. For example, it is possible that the first and/or second seal-off element 714, 715 of the double seal-off and column separation module 710 comprises an ultrahigh vacuum slider, a flap valve or a pendulum valve. Other embodiments for the first and/or second seal-off element 714, 715 are also possible. In this case, the first and/or second seal-off element 714, 715 can be configured to be operated manually, pneumatically or electrically. According to one example, the double seal-off and column separation module 710 is configured to realize an ultrahigh vacuum of 10⁻¹⁰ mbar or better. In addition or in an alternative, the double seal-off and column separation module 710 according to one example is configured to realize a leakage rate of less than or equal to 10⁻⁹ mbar/l/s.

To realize the vacuum or high vacuum during operation, the double seal-off and column separation module 710 comprises an access 717 in an intermediate region 716 between the first seal-off element 714 and the second seal-off element 715. As a result, the intermediate region 716 is evacuable for the operation of the multi-beam particle microscope 1, and the vacuum in the intermediate region 716 is breakable for the separation of the first and second partial module 711, 712 (cf. also FIG. 4B). In the example depicted in FIG. 2, the access 717 is realized by a simple drilled hole. However, it is also possible to realize a plurality of drilled holes or differently designed accesses. In the example shown, the drilled hole 717 is connected to a vacuum-tight line 718. The latter can be or can have been connected to a vacuum pump (not depicted).

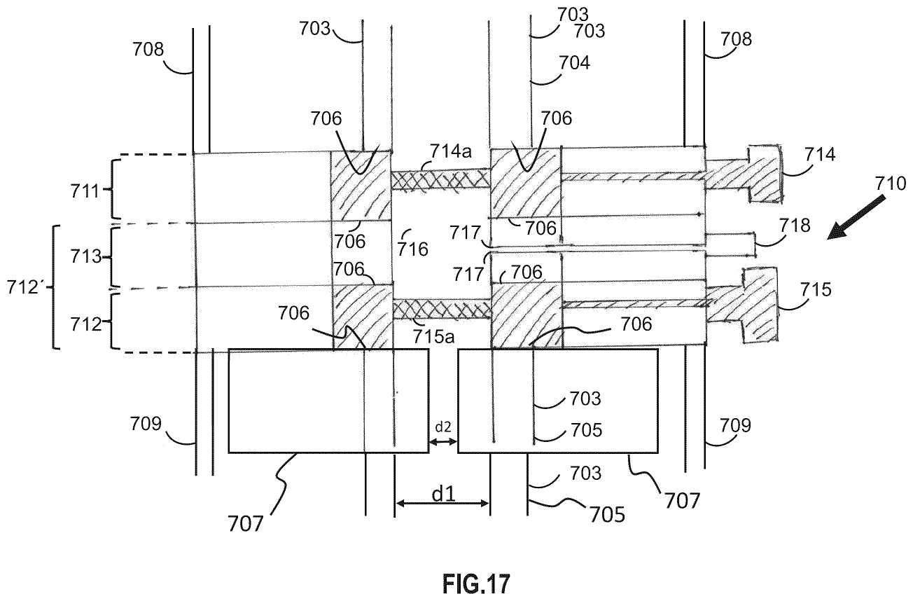

FIG. 17 schematically shows a sectional view of a double seal-off and column separation module 710 with a fill volume 707. This fill volume 707 serves to reduce the volume below the double seal-off and column separation module 710 in which vacuum should be created. For example, the fill volume 707 may comprise titanium or consist of titanium. Moreover, when the fill volume 707 comprises or consists of titanium, it can be a barrier for preventing a propagation of scattered radiation or a propagation of scattered electrons, to be precise both in the second partial module 712 of the double seal-off and column separation module 710 and in regions or modules of the multi-beam particle microscope 1 arranged therebelow in the direction of the particle-optical beam path. A charging of seals can also be reduced. In the example shown, the fill volume 707 has a through opening whose diameter d2 is smaller than a diameter d1 of the beam tube 703. This dimensioning also contributes to the reduction of scattered radiation.

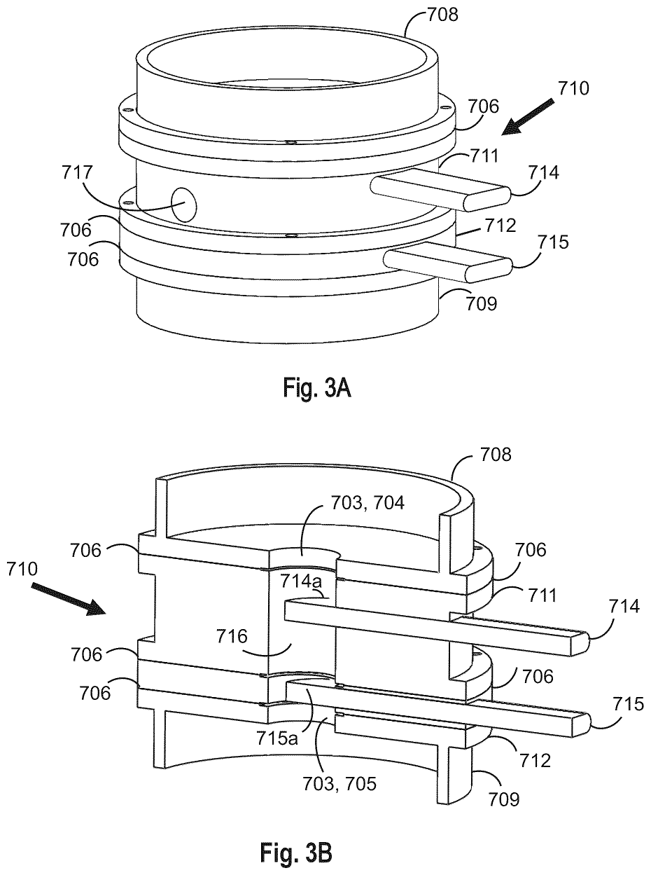

FIGS. 3A-3B schematically show a spatial representation of a double seal-off and column separation module 710. In the example shown, the housing 708, 709 of the illumination column is substantially tubular. Beam tube portions 704 and 705 of the beam tube 703 are respectively arranged within the housing 708, 709. The actual beam tube portions 704, 705, which continue in the illumination column on the particle source side and beam splitter side, respectively, have not been depicted explicitly in this way in FIGS. 3A-3B for reasons of clarity, however. Instead, FIG. 3A illustrates, in the perspective representation by way of example, a basic setup of the double seal-off and column separation module 710 and its integration in the illumination column. The first partial module 711 of the double seal-off and column separation module 710 is arranged on the housing 708 and also on the beam tube 703 arranged therein or the beam tube portion 704 arranged therein. In this case, the connection between the housing part 708 and the first partial module 711 is flange-like, wherein a scaling surface 706 is depicted in FIGS. 3A-3B by way of example. The quality of the seal or sealing surface generated thereby is desirable, especially in the region of the beam tube 703. The second partial module 712 is connected to the first partial module 711 via a further sealing surface 706. In turn, the second partial module 712 is sealingly connected to the housing 709 or to the beam tube 703 situated therein or the associated beam tube portion 705. In the depicted example, the first seal-off element 714 and the second seal-off element 715 are realized by an ultrahigh vacuum slider. To seal off, portions 714a and 715a are e.g. pushed or slid into the intermediate region 716 within the double seal-off and column separation module 710 in order to achieve the vacuum-tight closure. This can be identified particularly well in FIG. 3B, which shows a sectional representation of the double seal-off and column separation module 710. The double seal-off and column separation module 710 comprises an access 717 in the form of a drilled hole in an intermediate region 716 between the first seal-off element 714 and the second seal-off element 715. It is possible to connect a vacuum-tight line (not depicted) to this drilled hole 717 and the former is connectable or connected to a vacuum pump (not depicted) in turn. In this case, the access 717 itself is integrated in the first partial module 711 in the example shown. However, it is also possible to arrange the access 717 not in the first partial module 711 but for example within an intermediate piece or adapter between the two partial modules 711, 712. The double seal-off and column separation module 710 can comprise as few individual constituent parts or modules as possible, as this allows the sealing problems with regards to the generation and maintenance of the ultrahigh vacuum to be handled better. By contrast, the argument for an adapter piece can be that this allows the first partial module 711 and the second partial module 712 to be produced with an identical structure.

The double seal-off and column separation module 710 may comprise or consist of a material which is electrically conductive and for the relative permeability μᵣ of which the following applies: μᵣ≤1.005. As a result, the particle beam passing through the double seal-off and column separation module 710 is not interfered with and the double seal-off and column separation module is not charged or magnetized during the operation of the multi-beam particle microscope. Slightly recessing sealing surfaces 706 arranged in the region of the intermediate region 716, i.e. in the interior of the double seal-off and column separation module 710, from the cavity 716 or masking the sealing surfaces is also desirable for this reason, in order to avoid potential charging of the sealing surfaces 706.

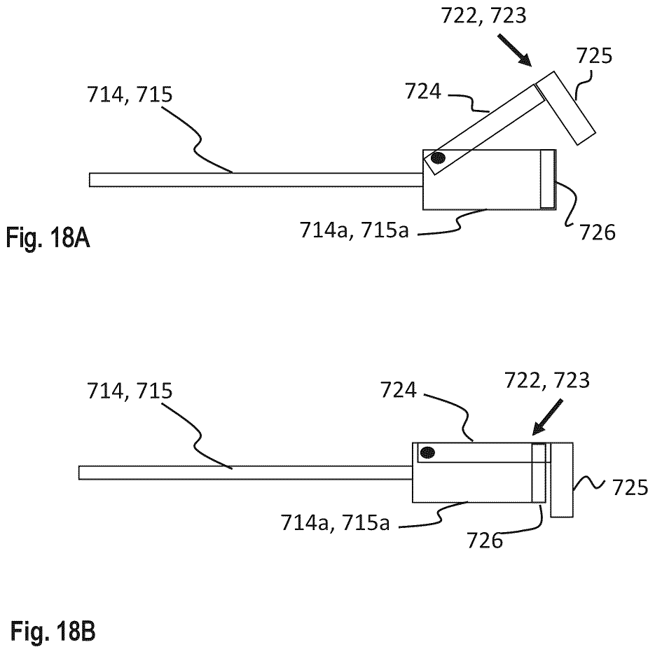

FIGS. 18A-18B schematically show a foldable shielding element 722, 723 for a seal 726. For example, the seal 726 may comprise a fluoro rubber or a fluoro elastomer, for example known by the trade name Viton®. The use of a seal 726 made of a fluoro rubber or a fluoro elastomer such as Viton®, for example, is desirable because a lower contact pressure than in the case of a metal seal is used for the sealing procedure. Moreover, such seals are comparatively soft and flexible, and this places lower demands on mechanical tolerances in the sealing region and on the surface roughness there. The shielding element 722, 723 consists of metal. The foldable shielding element 722, 723 comprises an upper region 724 and a lateral region 725, with the result that a housing or a type of garage is formed for the seal 726. The shielding element 722, 723 is closed if a valve of the double seal-off and column separation module 710 is open or if the multi-beam particle microscope 1 is evacuated and in operation (see FIG. 18A). Thus, the seal 726 can be protected against charging during operation. Potential scattered radiation, for example scattered electrons, can be captured and diverted by the metallic shielding element 722, 723. The seal 726 is only located freely outside of the shielding element 722, 723 when it is used for the double seal-off and column separation. The shielding element 722, 723 is open when the valve of the double seal-off and column separation module 710 is closed or if the double seal-off and column separation module 710 is separated, or should be separated, into the first partial module 711 and the second partial module 712 (see FIG. 18B).

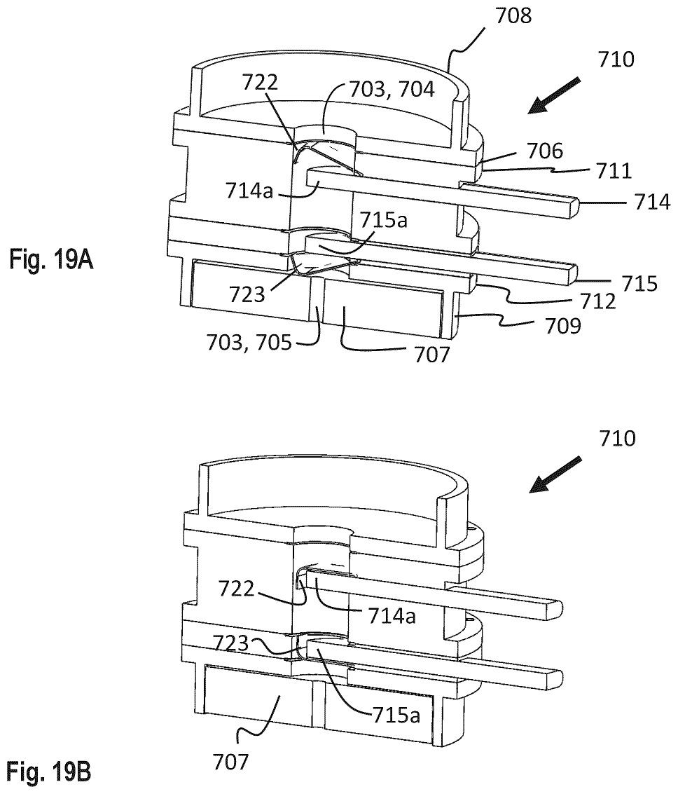

FIGS. 19A-b schematically shows a spatial representation of a double seal-off and column separation module 710 with a foldable shielding element 722, 723 for a seal 726 (not plotted explicitly in FIGS. 19A-b). The housing character or garage character of the foldable shielding element 722, 723 is readily visible in the spatial representation.

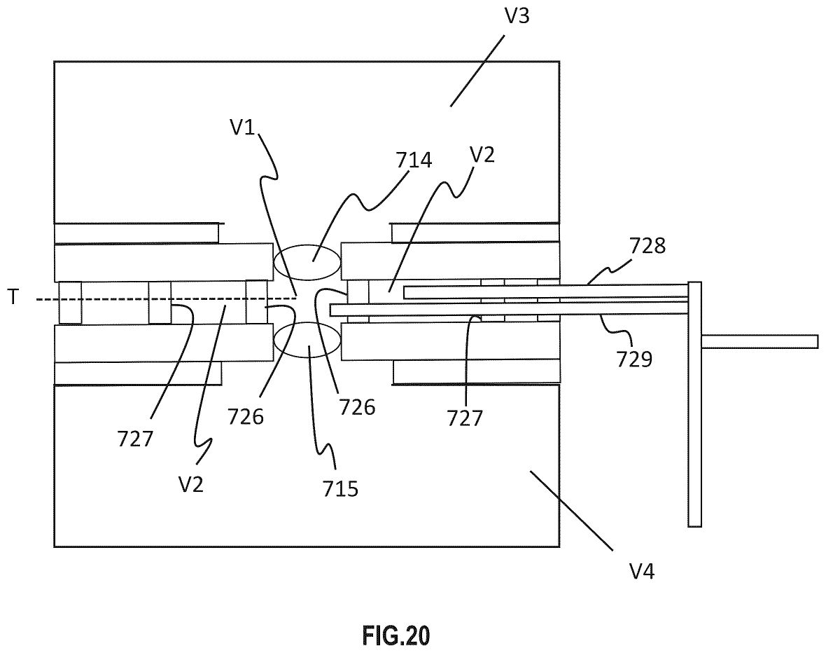

FIG. 20 schematically shows differential pumping in the case of a double seal-off and column separation module 710. If a seal made of fluoro rubber or made of a fluoro elastomer is used for the seal 726 in the separation plane T of the double seal-off and column separation module 710, then this seal 726 has very good sealing properties but nevertheless a higher leakage rate than a metal seal. This increased leakage rate might lead to an elevated UHV final pressure. To minimize or ideally eliminate this problem, the use of differential pumping in the separation plane T is proposed; this reduces the leakage rate since the pressure gradient is reduced. To this end, a further seal 727, which may be made of the same material as the seal 726, is provided. As a result, at least one additional pressure stage with the volume V2, arranged in the region between the two seals 726, 727, is created in addition to the volume V1 to be evacuated. The volume V1 is connected to a pump (not depicted) via a line 729; the volume V2 is connected to a pump (not depicted) via a line 728. The volumes V3 and V4 are depicted schematically and to be assigned to the evacuated volume within the column, respectively above and below the double seal-off and column separation module 710.

FIGS. 4A-4B schematically shows an illumination column 700 of a multi-beam particle microscope 1 and a double seal-off and column separation module 710 in a schematic representation. In this case, the housing 708, 709 of the illumination column 700 is depicted only schematically as a contour. The particle optics are situated within the housing, as has already been described in great detail in the context of FIG. 1. The sequence of the particle-optical constituent parts within the illumination column 700 is, by way of example, the following: At the top, the particle source 301 is arranged within the illumination column 700 or within the housing part 708. In the example shown, a condenser lens system with for example two magnetic condenser lenses 303.1 and 303.2 is situated therebelow. The multi-beam generator 305 is arranged therebelow in the particle-optical beam path. Below that in turn, a first field lens 308 is arranged, and this is followed by the arrangement of a further field lens 103. The beam splitter 400 is situated even further below in the particle-optical beam path.

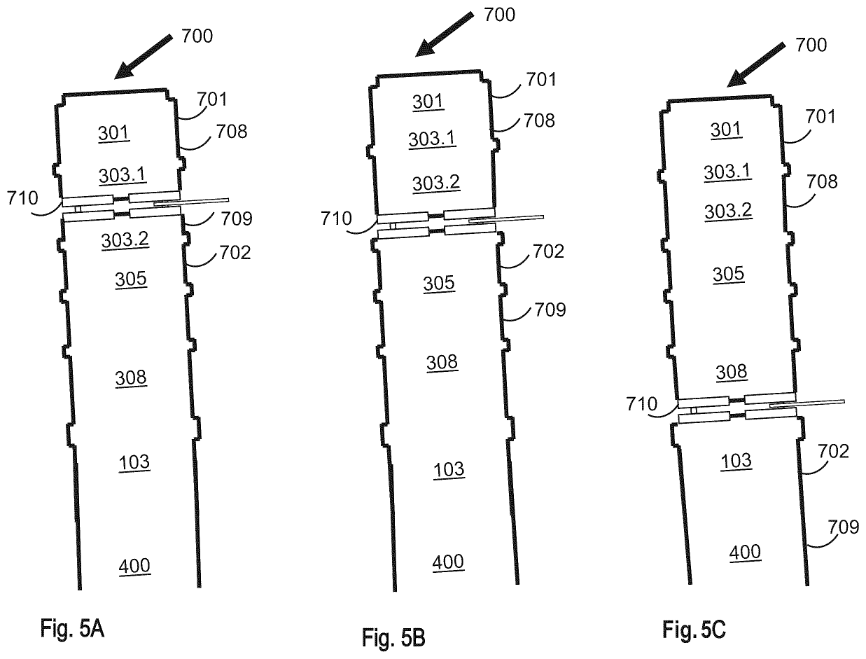

There are a number of options regarding the position in the illumination column 700 at which the double seal-off and column separation module 710 can be arranged: FIGS. 5A-5C schematically shows various possible arrangements of the double seal-off and column separation module 710 in the multi-beam particle microscope 1 or within the illumination column 700:

According to the exemplary embodiment depicted in FIG. 5A, the double seal-off and column separation module 710 is arranged within the condenser lens system 303 or, herein, between the first for example magnetic condenser lens 303.1 and the second for example magnetic condenser lens 303.2. In this way, the illumination column 700 is subdivided into the head of the illumination column 701 and into the remaining illumination column 702 or remaining column 702. The head of the illumination column 701, which always comprises the particle source 301 as well, forms the replacement module 701 in this case. The arrangement of the double seal-off and column separation module 710 in the depicted position is particularly space-saving since a drift path is provided between the two for example magnetic condenser lenses 303.1 and 303.2. An arrangement of the double seal-off and column separation module 710 within this drift path saves installation space or column height.

In the exemplary embodiment depicted in FIG. 5B, the double seal-off and column separation module 710 is arranged between the condenser lens system 303 and the multi-beam generator 305. The condenser lens system comprises two condenser lenses 303.1 and 303.2 in the example shown; however, it may naturally also comprise more than two condenser lenses. The depicted exemplary embodiment can be desirable because the replacement module 701 can be preconfigured or pre-adjusted to a greater extent. This relates for example to the complete pre-adjustment of particle source 301 and the entire condenser lens system 303.

According to the exemplary embodiment depicted in FIG. 5C, the double seal-off and column separation module 710 is arranged further down in the illumination column 700. For example, the double seal-off and column separation module 710 is arranged between the first field lens 308 and the second field lens 103 of the field lens system. In this embodiment variant, the replacement module 701 is even slightly larger than in the examples according to FIGS. 5A and 5B. This allows even more constituent parts of the replacement module 701 to be prequalified or pre-adjusted prior to a replacement of the particle source 301. For example, it is possible to optimally preset the incidence of the charged particles on the multi-beam generator 305 even before the replacement of the particle source 301. This in turn saves time during the actual replacement of the particle source 301. However, this is bought at the expense of a greater material and manufacturing outlay. Nevertheless, it is possible, following the replacement of the particle source 301, to reuse or refurbish one or more constituent parts of the replacement module 701 for a new replacement module 701.

In the example depicted in FIGS. 5A-5C, the following relation applies to an overall height h of the double seal-off and column separation module 710, measured in the installed state along the optical axis of the multi-beam particle microscope 1: h≤8.0 cm, such as h≤7.0 cm, for example h≤6.0 cm. In this case, the double seal-off and column separation module 710 has a minimum height h, due to design, for example approx. 5.0 cm, in order to ensure the desired stability and tightness of the double seal-off and column separation module 710.

It moreover holds true that, in all embodiment variants depicted in FIGS. 5A-5C, the particularly sensitive micro-optics of the multi-beam generator 305 are protected well during a replacement of the particle source 301: In the exemplary embodiments according to FIG. 5A and FIG. 5B, the lower seal-off element 715 is closed prior to the replacement of the particle source 301 or the removal of the replacement module 701. Thus, the multi-beam generator 305 or the micro-optics situated therein remain in the protective vacuum during the replacement. Then again, the problem of contamination of the micro-optics or of the multi-beam particle generator 305 does not arise in this way in the embodiment variant according to FIG. 5C since the latter is a constituent part of the replacement module 701.

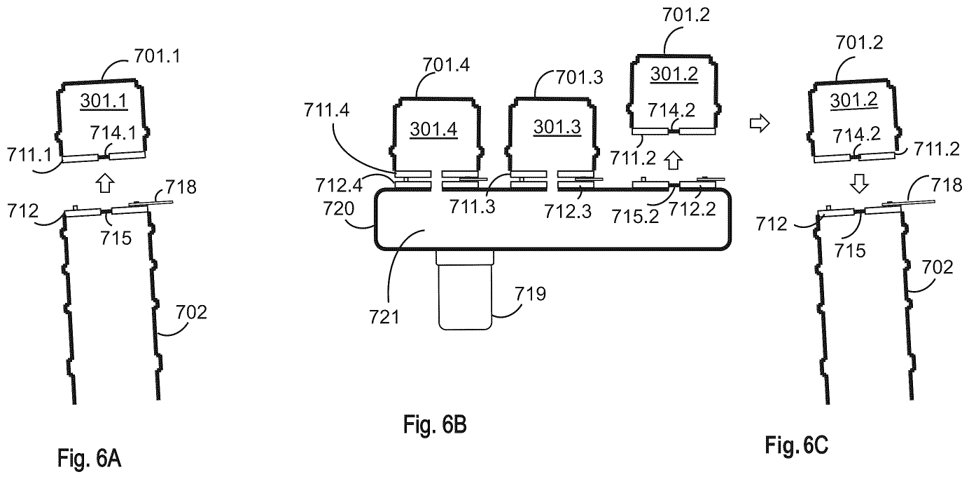

FIGS. 6A-b schematically illustrate the replacement of a particle source 301. In this case, the particle source 301 is arranged in the replacement module 701.1. Further constituent parts of the illumination column 700 can likewise be arranged in the replacement module 701.1; in this respect, FIGS. 6A-b only show the replacement scheme and no specific configuration of the replacement module 701.1, for example as depicted in FIGS. 5A-5C. In this case, the illumination column 700 is separated into the replacement module 701.1 and the remaining illumination column 702 via the double seal-off and column separation module 710. In FIG. 6A, the latter has already been spatially separated into its two partial modules, for example the first partial module 711.1 and the second partial module 712. In this case, the arrow in FIG. 6A should illustrate the spatial separation of the two partial modules 711.1 and 712. Each of the two seal-off elements 714.1 and 715 are closed during the separation procedure itself, with the result that the high vacuum situated in both the replacement module 701.1 and in the remaining column 702 can be maintained therein. The vacuum in the intermediate region 716 in the double seal-off and column separation module 710 was broken prior to separation, to be precise via an access as has already been explained in the context of the preceding figures. In the example shown, parts of the intermediate region or adapter pieces including an access and a supply line 718 remain arranged on the remaining column 702 or remain arranged on the second partial module 712 or have an integral embodiment with the latter in any case.

Once the replacement module 701.1 has been removed from the remaining illumination column 702, it is now possible to take a replacement particle source 301.2 from a depository 720 and place it on the remaining illumination column 702 in place of the original module 701.1. FIG. 6B illustrates this procedure:

In the example shown, the depository 720 comprises three storage spaces for three replacement modules 701.2, 701.3 and 701.4. Each of these comprise a new, i.e. unused particle source 301.2, 301.3 and 301.4. Each of the replacement modules 701.2, 701.3 and 701.4 are prequalified and/or pre-adjusted. Additionally, the replacement modules 701.2, 701.3 and 701.4 have already been evacuated and are stored with open seal-off elements 711, 712 in or on the depository 720. In the process, the interior 721 in the depository 720 is evacuated via the vacuum pump 719.

Now, before the replacement module 701.2, for example, is taken from the depository, the two seal-off elements 714.2 and 715.2 are closed. The vacuum in the intermediate region between the two seal-off elements 714.2, 715.2 is broken, with the result that the replacement module 701.2 can now be taken from the depository 720 without problems. The replacement module 701.2 is thereupon transferred to the remaining illumination column 702 and can be placed on the remaining column 702. The arrows in FIG. 6B in turn elucidate these movements. In this case, the first partial module 711.2 of the second replacement module 701.2 has an identical structure to the first partial module 711.1 of the old replacement module 701.1. Therefore, the first partial module 711.2 fits exactly on the second partial module 712, with the result that a new double seal-off and column separation module 710 can be assembled therefrom. After the replacement module 701.2 has been arranged on the remaining column 702, it is initially the intermediate region 716 between the first seal-off element 714.2 and the second seal-off element 715 that is evacuated. The intermediate region 716 can additionally be baked out, for example via a heating element arranged in the double seal-off and column separation module 710 (not depicted in the figures). After this comparatively short evacuation procedure and optional baking out of the double seal-off and column separation module 710, the seal-off elements 714.2 and 715 can then be opened again.

In the ideal case, the arrangement of the second replacement module 701.2 on the remaining part of the multi-beam particle microscope 1 or the remaining column 702 is implemented isostatically. In that case, no further adjustment of the replacement module 701.2 relative to the remaining column 702 is used. In addition or in an alternative, an adjustment of the second replacement module 701.2 can be implemented via an adjustment piece. In addition or in an alternative, the second replacement module 701.2 can be adjusted via electric and/or magnetic deflection fields which deflect the charged particles and/or the charged first individual particle beams. The multi-beam particle microscope 1 is operational with a new particle source 301.2 following these adjustment steps.

In general, the described replacement of a particle source 301 arranged in a replacement module 701 can be repeated, to be precise until all replacement modules 701 stored in the depository 720 have been installed. Moreover, it is naturally possible to fill vacated storage spaces in the depository 720 with new, already prequalified and pre-adjusted replacement modules 701. In this way, replacement modules with new particle sources 301 are always available. Moreover, it is naturally possible that replacement modules 701 for a plurality of multi-beam particle microscopes 1 are stored in the depository 720.

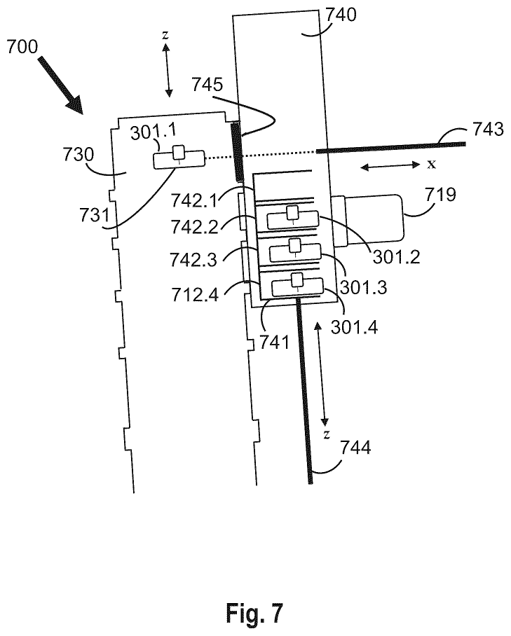

FIG. 7 schematically shows a detail of a multi-beam particle microscope 1 with a replaceable particle source. The illumination column 700 of the multi-beam particle microscope 1 comprises a first vacuum region 730 with a first particle source 301.1, which is arranged in an operational position 731 in the illumination column. Thus, the first particle source 301.1 is positioned and configured such that it can emit charged particles for the operation of the multi-beam particle microscope 1. A plurality of replacement particle sources 301.2, 301.3 and 301.4 have already been prequalified and/or pre-adjusted in this embodiment variant of the disclosure as well. They are situated in a storage unit 741 which comprises a multiplicity of storage positions 742.1, 742.2, 742.3 and 742.4. In this case, the storage unit 741 is arranged in a vacuum region 740. A high vacuum or ultrahigh vacuum can be provided in this vacuum region 740 via a vacuum pump 719.

Moreover, a transfer mechanism is provided for a vacuum transfer of a replacement particle source 301.2, 301.3, 301.4 from the storage unit 741 of the second vacuum region 740 into the operational position 731 in the first vacuum region 730. As a result, preconfigured replacement particle sources 301.2, 301.3, 301.4 structurally identical to the first particle source 301.1 can be brought into the operational position 731 when desired and can consequently serve as active particle source 301. The transfer mechanism can have a single-part or multi-part design and can be realized in technically different ways. In the example shown, the transfer mechanism comprises two transfer rods 743 and 744. The storage unit 741 can be displaced in the z-direction within the second vacuum region 740 by way of a movement of the transfer rod 744. As a result, the particle source 301 envisaged for the replacement can be moved into the desired z-position for the transfer in the narrower sense. For example, the transfer rod 743 which enables a displacement in the x-direction in the example shown can be used for the transfer of the replacement particle source from the second vacuum region 740 into the first vacuum region 730. A further constituent part of the transfer mechanism can be a stage, displaceable in the z-direction, of the illumination column 700. As a result, the operational position 731 of the active particle source 301.1 can be displaced in the z-direction and, when desired, be adapted to a transfer or handover position for a replacement particle source. In the example shown, the first vacuum region 730 and the second vacuum region 740 are designed as separate vacuum chambers 730, 740. An ultrahigh vacuum slider 745, which is opened during the transfer of the particle source 301, is arranged between the two regions 730, 740 or chambers 730, 740 in the example shown. However, it is also possible to form the two vacuum regions 730, 740 as a joint vacuum chamber and to provide no airlock and no slider between the two regions 730, 740. It can be the case that the transfer mechanism is further configured for a vacuum transfer of the first particle source 301.1 from the operational position 731 in the first vacuum region 730 into the storage unit 741 in the second vacuum region 740. For example, it is possible to use the same transfer rod 743 both to place a replacement particle source 301 in the illumination column 700 and also remove the replacement particle source again therefrom.

In this embodiment variant of the disclosure prequalified replacement particle sources 301.2, 301.3, 301.4 are already arranged in a vacuum region which is directly or indirectly connected to the vacuum region 730 of the illumination column. Thus, there is no provision for a separate depository with replacement particle sources or complete replacement modules. As a result, the replaced units can be smaller than in the case of the replacement modules 701 according to the embodiment variant of the disclosure which was described in FIGS. 2-6C. It could also be the that the replacement particle sources 301 are already integrated in the multi-beam particle microscope 1.

In the exemplary embodiment shown in FIG. 7, the storage unit 741 has a plurality of storage positions 742.1, 742.2, 742.3 and 742.4 which are arranged in accordance with a physically linear topology. In this case, the storage positions 742 are arranged one above the other in the z-direction and are brought into the transfer position by a linear displacement, namely in the z-direction. An alternative physically linear topology could also be designed such that the storage positions 742 are arranged successively in the x-direction. In this way, the replacement particle sources 301 could be successively brought into the operational position 731 and moved out of the illumination column 700 again on the other side.

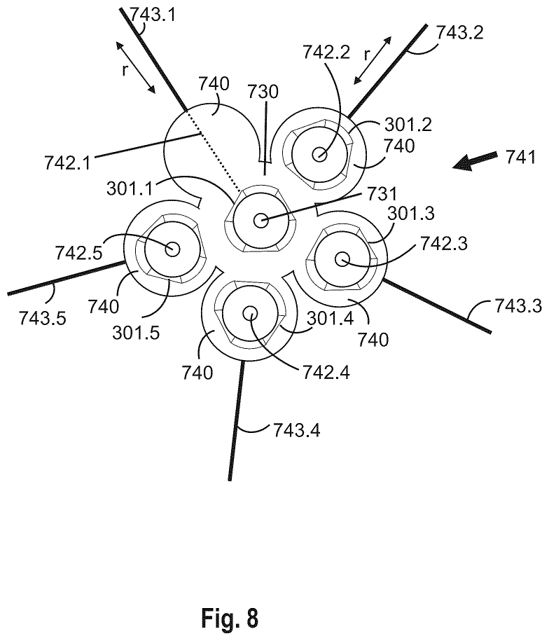

FIG. 8 schematically shows a further embodiment variant of the disclosure of a multi-beam particle microscope with a replaceable particle source 301. Replacement particle sources 301 are also arranged in a storage unit 741 in this embodiment variant. This storage unit 741 is situated in a vacuum region 740. In the example shown, the vacuum region 740 is formed integrally with the vacuum region 730 in which a particle source 301.1 is arranged in an operational position 731. In this case, FIG. 8 shows a schematic plan view of the active particle source 301.1 and of the replacement particle sources 301.2 to 301.5 in the storage unit 741.

The embodiment depicted in FIG. 8 differs from the embodiment depicted in FIG. 7 in terms of the topology of the storage unit 741 with the storage positions 742 present therein: According to the embodiment variant in FIG. 8, the storage unit 741 has a plurality of storage positions 742.1 to 742.5 which are arranged in accordance with a physically stellate topology. In the example shown, the storage positions 742.1 to 742.5 are located on an annulus. In this case, the replacement particle sources 301.1 to 301.5 can each be brought into the operational position 731 by virtue of a movement directed to the centre of the circle, i.e. a stellate movement. This movement is a movement in the radial direction r; it is indicated schematically in FIG. 8 by the double-headed arrows. Moreover, the first particle source 301.1, by way of example, has been brought from its storage position 742.1 into the operational position 731 by way of a radial movement using the transfer rod 743.1.

Once again, the replacement of the particle source 301 from the storage unit 741 in the operational position 731 is implemented completely in a vacuum or high vacuum in this embodiment variant of the disclosure. It is not necessary to initially break a vacuum and subsequently re-establish it. As a result, the replacement of the particle source 301 can be realized much quicker and contamination in the vacuum region 730, 740 is avoided in general. It is possible that the multi-beam particle microscope 1 is opened once all replacement particle sources 301.2 to 301.5 have been used or consumed, and, naturally, the vacuum is broken to this end. Then again, it is possible in that case to immediately equip the multi-beam particle microscope 1 with a multiplicity of particle sources 301, each of which has been prequalified and/or pre-adjusted. Overall, the time for the replacement of particle sources 301 is thus significantly reduced in this way too.

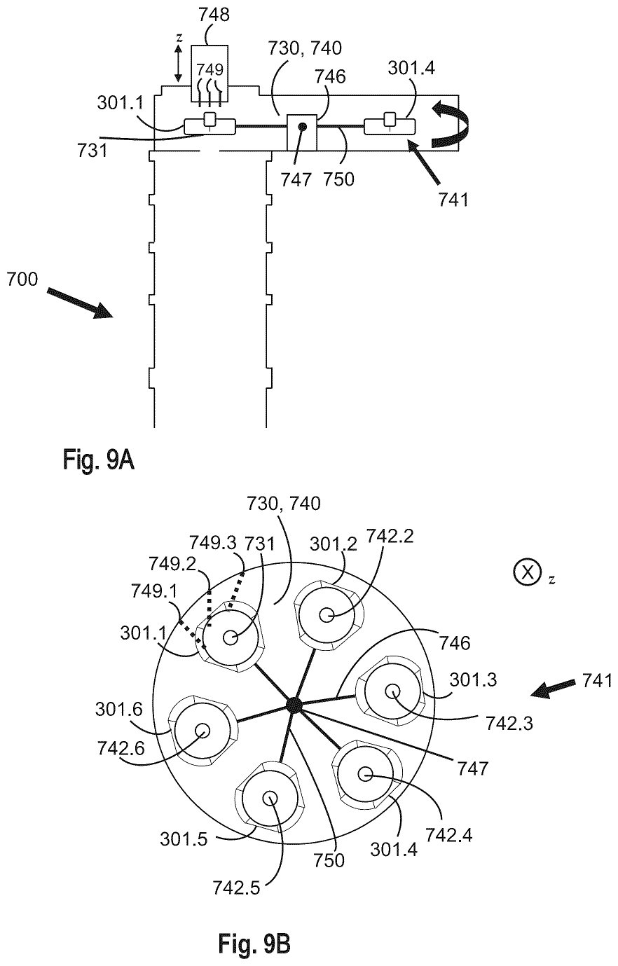

FIGS. 9A-9B show a further exemplary embodiment of a multi-beam particle microscope 1 with a replaceable particle source 301. In this case, FIG. 9A shows a schematic lateral sectional view and FIG. 9B shows a schematic plan view. Once again, this embodiment variant of the disclosure differs from the exemplary embodiments described in FIGS. 7 and 8 by way of the topology: Provision is made of a storage unit 741 having a plurality of storage positions 742.2 to 742.6 for the replacement particle sources 301.2 to 301.6, which are arranged in accordance with a physically ring-shaped topology. The operational position 731 for the active particle source 301.1 is also situated on this ring or annulus as well. In the example shown, this physically ring-shaped topology is realized via a carousel 746. The physically ring-shaped topology could also be referred to as a turret topology. In this case, the carousel 746 comprises rods or a linkage 750, with the carousel 746 being rotatable about a centre of rotation 747. This allows the replacement particle sources 301.2 to 301.6 to be rotated into the operational position 731.

A contacting unit 748 with electrical contacts 749.1 to 749.3 is also depicted in this embodiment of the disclosure by way of example. This contacting unit 748 serves for electrical contacting of the respectively active particle source 301 in the operational position 731. For example, this may relate to resilient sliding contacts for establishing an electrical connection (cf. FIG. 9B). In an alternative, the contacting unit 748 may be movable in the Z-direction via a Z-stage, and so the contacting unit 748 can be connected like a connector to the respectively active particle source 301. It should be observed in this context that these contacts 749.1, 749.2 and 749.3 are contacts usable for high-voltage purposes. For example, a tip cathode, an extractor stop and an anode stop of the particle source 301 can be contacted via the contacts 749.1, 749.2 and 749.3.

In all embodiment variants depicted in FIGS. 7-9B, provision can optionally be made of an adjustment unit for fine positioning of the respectively active particle source 301 in the operational position 731. In this context, the adjustment unit can once again have a single-part or multi-part design. For example, it can be realized by way of a 3-D stage and/or by way of piezoelectric elements. Other embodiments are also possible.

In general, it also holds true in the embodiment variants of the disclosure depicted in FIGS. 7-9B that each replacement particle source 301 comprises a tip cathode, an extractor electrode and an anode, which have already been adjusted relative to one another and/or technically prequalified. Consequently, it is possible to largely or completely make do without fine adjustments of the constituent parts of the replacement particle source 301 relative to one another in this embodiment variant, and this saves time.

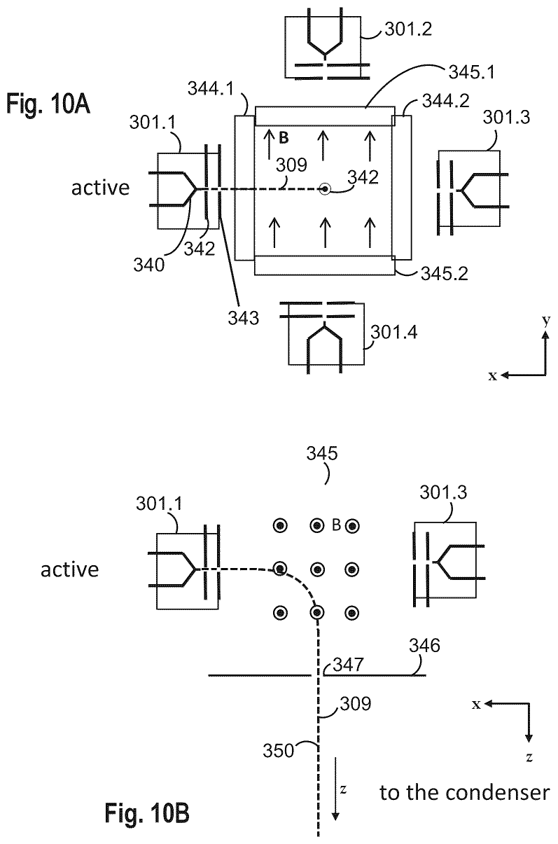

FIGS. 10A-10B schematically show a portion of a multi-beam particle microscope 1 with a replaceable particle source 301, wherein the replacement is implemented by way of a switchover. According to this embodiment of the disclosure, a plurality of structurally identical particle sources 301.1 to 301.4 have spatially fixed arrangement. Thus, there is no need to transfer or move a particle source 301 from a storage position to an operational position. A transfer mechanism has been replaced by a switching mechanism configured to switch between the particle sources 301.1 to 301.4 such that only exactly one of the particle sources 301.1 to 301.4 is an active particle source emitting charged particles 309 at any one time in each case. In this case, the controller 10 of the multi-beam particle microscope 1 is configured to control the switching mechanism for the switchover. This is accompanied by the control of the particle sources 301.1 to 301.4, and so only exactly one of the particle sources 301 represents an active particle source 301.1 at any one time.

So that the emitted charged particles 309 can be precisely coupled into the illumination column 700 of the multi-beam particle microscope 1 from each of the particle sources 301.1 to 301.4 or from each operational position, this embodiment of the disclosure provides for an electric and/or magnetic deflection mechanism configured to deflect the charged particles 309 emitted by the respectively active particle source 301.1 onto the optical axis 350 of the multi-beam particle microscope 1. In this case, the controller 10 of the multi-beam particle microscope 1 is configured to also control the deflection mechanism.

In the exemplary embodiment shown in FIGS. 10A-10B, the multi-beam particle microscope 1 comprises exactly four particle sources 301.1 to 301.4 which are arranged opposite one another in pairs and which moreover are arranged such that each of the particle sources 301.1 to 301.4 can emit charged particles 309 orthogonally to the optical axis 350 of the multi-beam particle microscope 1. In the plan view according to FIG. 10A, the optical axis points into the plane of the drawing; the optical axis 350 runs in the z-direction. In the shown example, the particle sources 301.1 and 301.3 are moreover arranged as a pair and opposite one another. A corresponding statement applies to the particle sources 301.2 and 301.4. Naturally, all particle sources 301.1 to 301.4 are arranged in the vacuum or high vacuum in this case.

In the exemplary embodiment shown in FIGS. 10A-10B, the deflection mechanism comprises two pairs of Helmholtz coils 344, 345, and hence a total of four coils 344.1, 344.2, 345.1 and 345.2, wherein only one pair of Helmholtz coil pairs 344, 345 is active at any one time in each case. In this case, a coil 344.1, 344.2, 345.1, 345.2 is respectively arranged between one of the particle sources 301.1 to 301.4 and the optical axis 350 or an imaginary extension of the optical axis 350 of the multi-beam particle microscope 1. In this case, the axes of the two Helmholtz coil pairs 344, 345 are arranged orthogonal to the optical axis 350 of the multi-beam particle microscope 1, and so a magnetic field B generable in each case by a Helmholtz coil pair 344, 345 is oriented orthogonal to the optical axis 350 of the multi-beam particle microscope 1. In this case, the controller 10 is configured to control the Helmholtz coil pairs 344, 345 in such a way that the charged particles 309 emitted by the respectively active particle source 301 are deflected in the direction of the optical axis 350 of the multi-beam particle microscope 1.

In the example according to FIG. 10A, the particle source 301.1, as active particle source, emits charged particles 309. These pass through the opening in the coil 344.1 of the Helmholtz coil pair 344, with the Helmholtz coil pair 344 not being active in that case. Instead, the Helmholtz coil pair 345 with the two Helmholtz coils 345.1 and 345.2 is active, with the result that the emitted charged particles 309 experience a magnetic field B oriented orthogonal to their emission direction and also orthogonal to the optical axis 350 of the multi-beam particle microscope 1. The charged particles 309 are deflected on a circular trajectory. In the example shown, the charged particles 309 describe a quarter circular arc. This is depicted in FIG. 10B which shows a side view through the particle source region or head of the multi-beam particle microscope 1. Following a deflection through 90°, the charged particles 309 leave the magnetic field of the Helmholtz coil pair 345 in the example shown and pass through a stop 346 with an aperture 347. The orientation of the charged particles 309 now is parallel to the optical axis 350 or to the z-direction. Next, the charged particles 309 reach a condenser lens system or collimation lens system 303 (not depicted in FIG. 10).

If there now is a switchover between the particle source 301.1 and the particle source 301.2, for example, then the particle source 301.2 becomes the active particle source and the particle source 301.1 becomes inactive. Moreover, the Helmholtz coil pair 345 is deactivated and the Helmholtz coil pair 344 is activated instead. A corresponding procedure can also be implemented for the replacement particle sources 301.3 and 301.4.

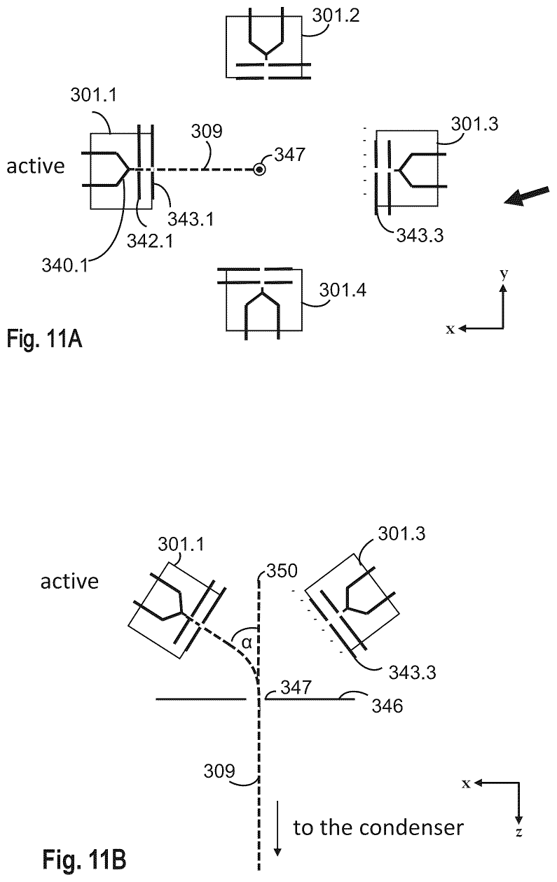

FIGS. 11A-11B show a further embodiment variant of the disclosure, in which the replacement of the particle sources 301 is likewise not implemented by a mechanical transfer but by a switchover. The exemplary embodiment depicted in FIGS. 11A-11B substantially differs from the exemplary embodiment depicted in FIGS. 10A-10B by way of the design of the deflection mechanism: An electrical deflection mechanism is used in the embodiment variant according to FIGS. 11A-11B. Moreover, the arrangement of the particle sources 301.1 to 301.4 is slightly different to that in FIGS. 10A-10B: This is because the particle sources 301.1 to 301.4 opposite one another in pairwise fashion are each arranged tilted at an angle α with respect to the optical axis 350 of the multi-beam particle microscope 1. FIG. 11B shows this best; in it, a side view is depicted schematically: The particle sources 301.1 and 301.3 opposite one another as a pair are tilted through approximately 45° with respect to the optical axis 350 of the multi-beam particle microscope 1. However, the angle α can also be slightly larger or slightly smaller, for example 40°≤α≤50°. In the example shown, the deflection mechanism comprises four deflection electrodes which correspond to the four anodes 343.1 to 343.4 of the four particle sources 301.1 to 301.4 in the example shown. However, it is also possible to provide the four deflection electrodes separately, that is to say separate from the four anodes 343.1 to 343.4 of the four particle sources 301.1 to 301.4. The controller 10 is configured to use a deflection potential to control the deflection electrode of the particle source 301 in each case opposite the active particle source 301, in such a way that the charged particles emitted by the respectively active particle source 301 are deflected in the direction of the optical axis 350 of the multi-beam particle microscope 1. The particle source 301.1 is active in the example according to FIGS. 11A-11B. The particle source 301.3 with its deflection electrode 343.3, identical to the anode of the particle source 301.3 in the example shown, is opposite the active particle source. The function of the deflection electrode as deflection electrode 343.3 is obtained solely by the corresponding control of the particle source 301.3 or, in the depicted exemplary case, only of the anode 343.3 of the particle source 301.3. In FIGS. 11A-11B, the deflection potential is indicated in each case by the negative signs in front of the anode 343.3. Otherwise, the embodiment variant depicted in FIGS. 11A-11B is identical to the representation shown in FIGS. 10A-10B: The charged particles 309 deflected onto the optical axis 350 pass the stop 346 through the aperture 347 and continue on their path to the condenser 303.

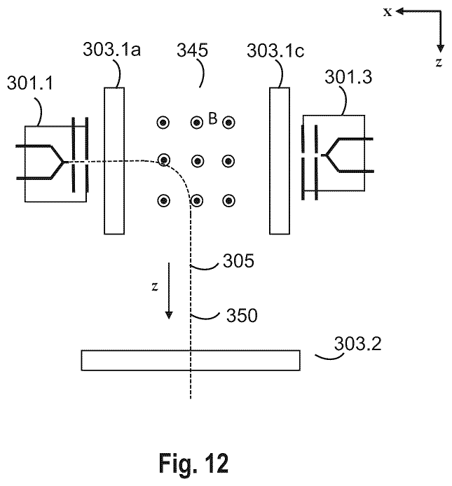

FIG. 12 schematically shows a further embodiment variant of the disclosure for a multi-beam particle microscope 1 with a replaceable particle source 301, wherein the replacement is once again implemented by way of a switchover. The exemplary embodiment depicted in FIG. 12 differs from the exemplary embodiment depicted in FIGS. 10A-10B by way of the position of the condenser lens system 303: In the embodiment variant according to FIG. 12, the condenser lens system 303 is installed further up, namely already before the charged particles 309 are coupled onto the (common) optical axis 350 of the multi-beam particle microscope 1. The charged particles 309 already pass through a first magnetic lens 303. 1a of the condenser lens system before the emitted charged particles 309 enter into the deflection mechanism or magnetic field of a Helmholtz coil pair 345. A second magnetic condenser lens 303.2 is arranged downstream of the deflection mechanism 344, 345 and centred around the optical axis 350. Thus, in this embodiment of the disclosure each particle source 301.1 is additionally provided with a magnetic condenser lens 303.1a to 303.1d assigned to this particle source (i.e., four additional magnetic lenses). The embodiment of the disclosure depicted in FIG. 12 thus saves even more space than the embodiment variant depicted in FIGS. 10A-10B.

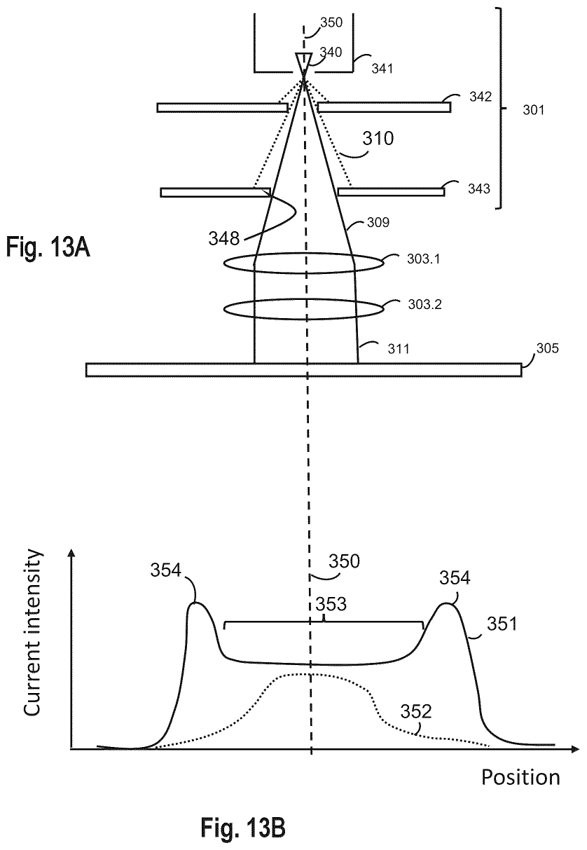

FIGS. 13A-13B schematically shows a multi-beam particle source 301 and a position dependence of its current intensity. In the example shown, the particle source 301 is constructed as follows: It comprises a cathode tip 340 which is surrounded in the style of a lateral cylinder surface by a suppressor electrode 341, the suppressor electrode 341 serving to suppress a lateral emergence of electrons from the cathode tip 340. For example, the cathode tip 340 can be a thermal field emitter that is operated with a heating current of a few amperes. A voltage of a few hundred volts relative to the cathode tip 340 is applied to the suppressor 341. A voltage of several kilovolts relative to the cathode tip 340 is applied to the extractor electrode 342 that is arranged at a distance from the cathode tip 340. The anode 343 is arranged below the extractor 342 or approximately one centimetre below the cathode tip 340. The acceleration potential between tip 340 and anode 343 is several ten thousand kilovolt, for example 25 kV, 30 kV or 35 kV. A condenser lens system with magnetic condenser lenses 303.1 and 303.2 is arranged in the particle-optical beam path downstream of the particle source 301. This shapes a collimated particle beam 311, and the latter is incident on a first plate (filter plate) of a multi-beam generator 305 (only depicted in sections in FIG. 13A).

In the exemplary embodiment illustrated, the anode 343 is designed as an anode stop with a central anode aperture 348. Part of the beam cone 310 emitted by the tip 340 is cut off at the aperture 348.

FIG. 13B depicts a current intensity of the emitted charged particles in a sectional illustration through the optical axis 350: In this context, the curve 351 shows the current intensity of a new particle source 301 while the curve 352 shows the curve of an old particle source 301, which is consequently to be replaced. There is a plateau region 353 in the case of the new particle source 301 or the curve 351. The current intensity is very homogeneous in this region and this plateau 353 can therefore be used very well for the generation of a multiplicity of individual particle beams with the same beam current density. For this reason, the plateau 353 should ideally correspond to the opening region 348 of the anode stop 343. The teeth 354 of the curve 351 are cut off by the anode stop 343 in the example shown. Now, if the cathode tip 340 is not in an optimal position, i.e. not exactly on the optical axis 350, then the curve 351 is also displaced in relation to the optical axis 350. Thus, if the anode stop 343 is provided with a sensor system then it is possible to establish by way of a spatially resolved measurement of the current intensity as to whether the cathode tip 340 is aligned precisely with respect to the optical axis 350 and/or precisely with respect to the centre of the anode opening 348. A readjustment or fine adjustment of the corresponding alignment of the cathode tip 340 then is possible on the basis of such a current pattern measurement. For example, it is possible to displace the cathode tip 340 relative to the extractor 342 and/or to the anode 343 in all spatial directions. In addition or in an alternative, a rotation about these axes/spatial directions is possible, for example via a hexapod.

In addition or in an alternative, it is also possible to monitor the current intensity or a current pattern in the region of the particle source 301. It is then possible on the basis of the current pattern to predict a remaining service life of the particle source 301 and, for example, initiate a replacement of the particle source 301. In general, it is known that the emission characteristic of a particle source 301 changes over the course of the service life of the particle source 301, and how it typically changes. An example to this end is the curve 352 in FIG. 13B: The teeth 354 no longer exist in the current intensity curve 352 of an old particle source 301. There is no real plateau any more either. Additionally, there are also changes in the absolute current intensity, with the current intensity normally increasing strongly one more time shortly prior to the failure of a particle source 301. On the basis of this insight, it is possible to predict the remaining service life of the particle source 301 and, for example, also initiate the replacement of the particle source 301 in timely fashion.

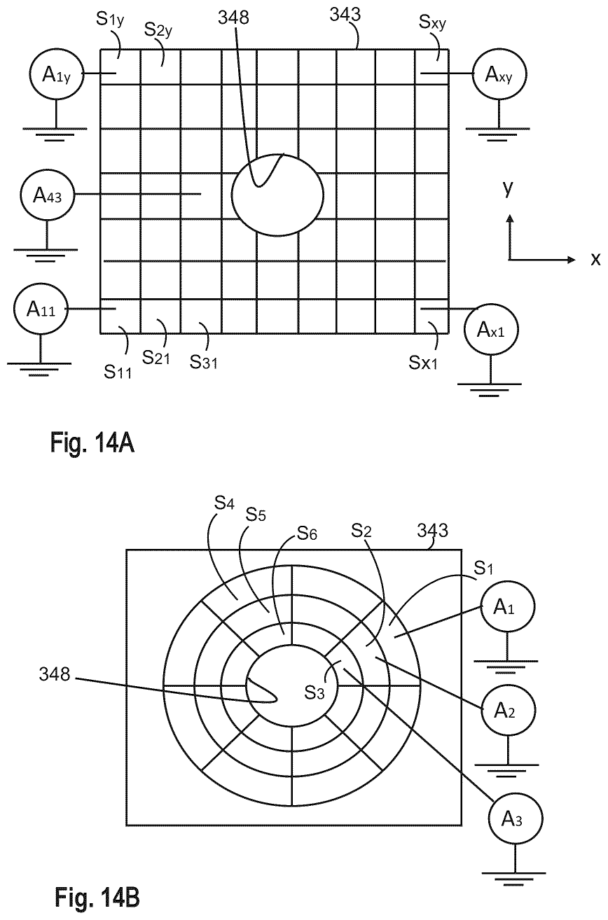

FIGS. 14A-14B schematically show a current pattern acquisition at an anode stop 343, which can be used to finely adjust the particle source 301. In addition or in an alternative, the current pattern acquisition can also be used to predict the service life of the current particle source 301 and/or initiate the replacement of the active particle source 301. In general, a current pattern can be acquired in the region of the particle source 301 in different ways. By way of example, the current pattern acquisition at the anode stop 343 is described. However, it is naturally possible to perform the current pattern acquisition in completely analogous fashion on the extractor stop 342 or even on a further, separately provided stop. FIGS. 14A-14B merely shows a concept in this respect:

The anode stop 343 comprises a central opening 348, through which some of the emitted particles 309 pass. Typically, these are those particles which contribute to the plateau 353 of the current intensity (cf. FIG. 13B). Emitted particles are also incident on the anode stop 343 around the anode aperture 348. The current intensity or beam current density of these charged particles cut off by the stop 343 can now be ascertained with spatial or local resolution. To this end, the anode stop 343 according to FIG. 14A is subdivided into various sectors S₁₁ to S_{xy}. A separate beam current measurement can be performed in each of these sectors Sᵢⱼ. In the simplest case, a multiplicity of highly sensitive ammeters are used to this end, for example picometers. In this case, the individual sectors Sᵢⱼ are insulated from one another. It is possible that the sectors Sᵢⱼ are in the form of shaped sensor plates, their insulation from one another being implemented in hidden fashion by way of a labyrinth such that charging of the insulator by charged particles between sectors can be prevented as a result. In an alternative, it is possible to design the individual sectors Sᵢⱼ as scintillators. Other embodiments for the current pattern acquisition are also possible.

FIG. 14B shows a different geometric arrangement of sectors Sᵢⱼ for acquiring a spatially resolved current pattern. Three concentric rings, in turn subdivided into individual sectors Sᵢ, are provided in the example shown. There is a separate beam current measurement for each sector Sᵢ. For reasons of clarity, FIGS. 14A-14B do not plot all sectors and also does not plot all current measuring devices.

In addition or in an alternative, it is possible to monitor the beam current in a different way as well, in order to draw conclusions about the remaining service life of the active particle source 301 in this way. In this context, reference is made yet again to WO 2023/001402 A1, which has already been cited previously.

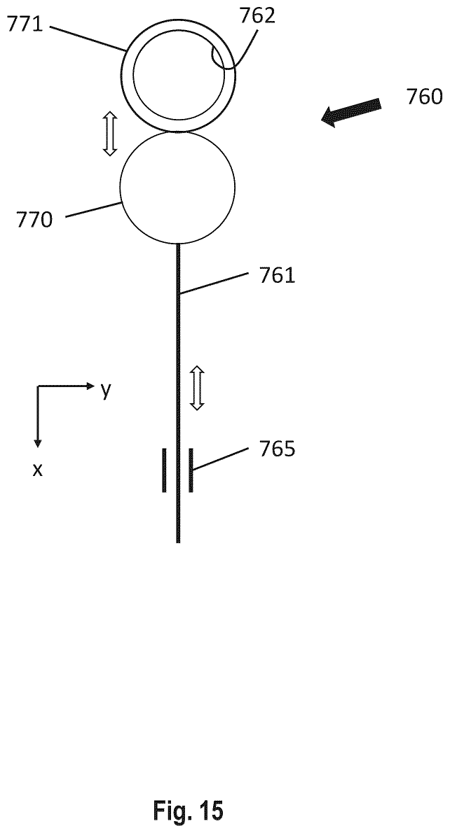

FIG. 15 schematically shows a plan view of a metallic covering element 760 that is insertable into the beam path of a multi-beam particle microscope 1. The electrically conductive covering element 760 comprises a particle protection 770, which serves as covering element in the narrower sense, and a region 770 which substantially serves as beam tube extension. This region 770, tubular in the example shown, can be realized by a circular through opening 762 in the covering element 760. In the example shown, the covering element 760 comprises a metallic cantilever which is displaceable in the x-direction and hence displaceable orthogonal to the optical axis (the latter points into the plane of the drawing in FIG. 15, i.e. in the z-direction). In FIG. 15, this displaceability is indicated by the double-headed arrow. The covering element 760 is held and guided by the element 765, and so a displacement in the x-direction can be implemented precisely. In relation to the particle-optical beam path in a multi-beam particle microscope, the covering element 760 may be arranged above a multi-beam generator 305, with the result that the multi-beam generator 305 is covered by the covering element 760 in the inserted state. The particle protection 770 closes off or covers the beam tube in that case. The beam tube is open in the non-inserted state; the charged particles pass through the through opening in the covering element. The electrically conductive covering element 760 can be embodied in different ways; in this respect, FIG. 15 only shows a functional concept. For example, the covering element 760 can be designed as a metallic slider or metallic cantilever, or as a movable disc. This cover via the particle protection 770 additionally protects the multi-beam generator 305 during a replacement of the particle source 301. During a replacement of the particle source 301, the electrically conductive covering element then serves not only to protect against contamination but also to protect electronic components installed in the multi-beam generator 305 against scattered electrons and/or high-energy light radiation. Moreover, it is possible to provide a multi-beam particle microscope 1 with the described electrically conductive covering element 760 but without the double seal-off and column separation module 710 according to the disclosure.

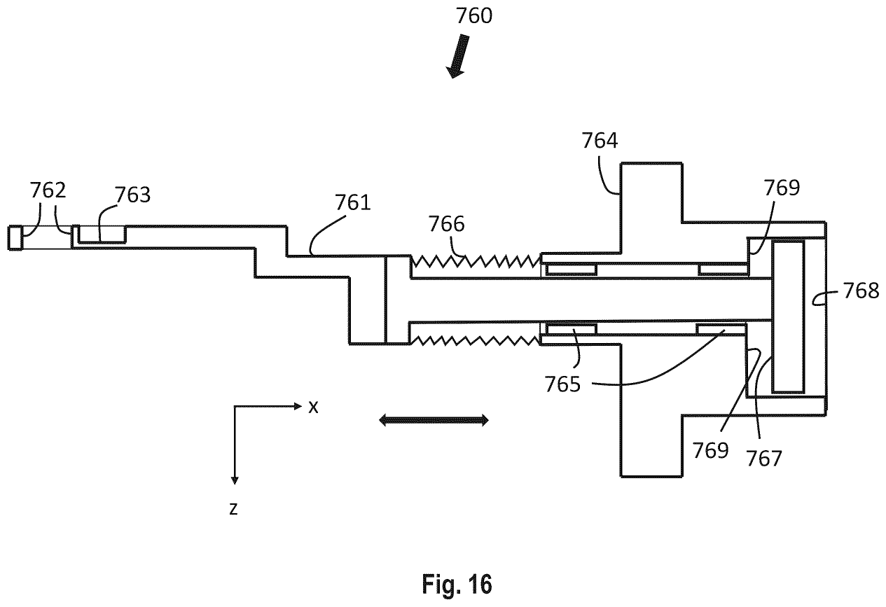

FIG. 16 schematically shows a lateral section of an exemplary configuration of a covering element 760. According to this exemplary embodiment, the covering element 760 comprises a metallic cantilever 761 or is in the form of a metallic cantilever 761 which is displaceable orthogonal to the particle-optical beam path, in this case in the x-direction, between a first stop position 768 and a second stop position 769. For example, the two stops 768, 769 can be formed by a main body 764, which is connected fixedly in space to a housing 708, 709 of a multi-beam particle microscope 1. For example, the cantilever 761 can be supported by and guided through a linear bushing 765. The metallic cantilever 761 has a through opening 762, the diameter of which can be matched to a beam tube diameter of the beam tube adjacent to the through opening. Through the through opening 762, charged particles are able to pass through the covering element 760 unimpeded when the covering element is in the first stop position 768. Moreover, the cantilever 761 has an for example circular depression 763, the diameter of which can be likewise matched to the beam tube diameter of the adjacent beam tube. If the cantilever 761 is in the second stop position, charged particles are incident on the depression during the operation of the multi-beam particle microscope 1. When the housing 708, 709 is open and/or the vacuum in the multi-beam particle microscope 1 is broken, particles which could otherwise penetrate into the lower region of the illumination column 700 are incident on the depression. In this way, an additional particle protection arises during a replacement of a particle source 301. In addition to the protective function, this embodiment variant has the further feature that it can be used for beam current measuring purposes, and hence for monitoring purposes and/or adjustment purposes: This is because, according to an embodiment of the disclosure, a beam current meter is arranged in the for example circular depression 763 and/or the circular depression 763 is connected to a beam current meter. For example, this renders it possible to measure scattered electrons. In an alternative or in addition, the direct beam current can also be measured during the operation of the multi-beam particle microscope 1.

According to an embodiment variant, the metallic cantilever 760 has a predetermined thickness and extends transversely to the entire beam tube 703 or through the latter. In general, this achieves a lengthening of the beam tube 703, and it is possible to better protect the multi-beam generator 305 with electronics and/or circuits situated thereon, for example against arising x-ray radiation. The beam current meter is also able to ascertain a beam current directly or indirectly in this embodiment variant. In the case of this embodiment variant, too, it is possible in general to record or monitor the beam current with spatial resolution. In this case, the spatial resolution can be implemented in a manner analogous to certain concepts described in FIGS. 13A-13B and FIGS. 14A-14B.

The exemplary embodiments described should not be construed as limiting for the disclosure but instead merely serve for the better understanding thereof. Moreover, the exemplary embodiments described in the figures can also be combined with one another in full or in part, provided that no technical contradictions arise as a result.

### LIST OF REFERENCE SIGNS

1 Multi-beam particle microscope
3 Primary particle beams, first individual particle beams
5 Beam spots, incidence locations
7 Object, sample, wafer
9 Secondary particle beams, second individual particle beams
10 Computer system, controller
15 Sample surface, wafer surface
25 Image point of a second individual particle beam
101 Object plane
102 Objective lens
103 Field lens
105 Axis
200 Detector system
205 Projection lens system
206 Projection lens
207 Multi-particle detector
208 Projection lens
209 Projection lens
210 Projection lens
212 Cross-over
214 Aperture filter, contrast stop
220 Multi-aperture corrector, individual deflector array
222 Collective anti-deflection system
300 Beam generating apparatus
301 Particle source
303 Collimation lens system
305 Multi-aperture arrangement, multi-beam particle generator
306 Micro-optics with multi-aperture plates
307 Field lens
308 Field lens
309 Particle beam
310 Outer beam cone
311 Collimated particle beam
321 Intermediate image plane
323 Beam foci
340 Cathode tip
342 Extractor, extractor stop
343 Anode, anode stop
344 Helmholtz coil pair
345 Helmholtz coil pair
346 Stop
347 Aperture
348 Aperture
350 Optical axis
351 Current intensity of a new particle source
352 Current intensity of an old particle source
353 Plateau
354 Teeth
400 Beam splitter, magnet arrangement
500 Scan deflector
503 Voltage source
600 Displacement stage or positioning device
700 Illumination column
701 Head of the illumination column, replacement module
702 Remaining illumination column, remaining column
703 Beam tube
704 First beam tube portion
705 Second beam tube portion
706 Sealing surface
707 Fill volume
708 Housing
709 Housing
710 Double seal-off and column separation module
711 First partial module
712 Second partial module
713 Intermediate piece, adapter
714 First seal-off element
715 Second seal-off element
716 Intermediate region
717 Access, drilled hole
718 Vacuum-tight line
719 Vacuum pump
720 Depository
721 Evacuated region in the depository
722 Shielding element
723 Shielding element
724 Upper region
725 Lateral region
726 Seal
727 Seal
728 Line
729 Line
730 First vacuum region
731 Operational position
740 Second vacuum region
741 Storage unit
742 Storage position
743 Transfer rod
744 Transfer rod
745 Ultrahigh vacuum slider
746 Carousel
747 Centre of rotation
748 Contacting unit
749 Electrical contact
750 Rod, linkage
760 Covering element
761 Metallic cantilever
762 Through opening
763 Circular depression
764 Main body
765 Holder, guide
766 Diaphragm bellows
767 Abutment body
768 First stop
769 Second stop
770 Particle protection
771 Beam tube extension
V1 Volume
V2 Volume
V3 Volume
V4 Volume
T Separation plane, separation region

What is claimed is:

1. A multi-beam particle microscope, comprising:
a particle source configured to emit charged particles;
a multi-beam generator configured to generate a first field of a multiplicity of charged first individual particle beams from the charged particles;
a first particle-optical unit having a first particle-optical beam path, the first particle-optical unit configured to image the first individual particle beams onto a sample surface in an object plane of the multi-beam particle microscope so that the first individual particle beams are incident on the sample surface at incidence locations configured to define a second field;
a detection system with a multiplicity of detection regions configured to define a third field;
a second particle-optical unit having a second particle-optical beam path, the second particle-optical unit configured to image second individual particle beams emanating from the incidence locations in the second field onto the third field;
a magnetic and/or electrostatic objective lens configured to have the first and the second individual particle beams pass therethrough;
a beam splitter in the first particle-optical beam path between the multi-beam generator and the objective lens, the beam splitter being in the second particle-optical beam path between the objective lens and the detection system;
a beam tube comprising first and second beam tube portions between the particle source and the beam splitter, the beam tube being evacuated during operation of the multi-beam particle microscope, the beam tube configured to guide the charged particles or the charged individual particle beams within the beam tube during the operation of the multi-beam particle microscope; and
a double seal-off and column separation module sealingly arranged between the first and second beam tube portions during the operation of the multi-beam particle microscope and through which the charged particles or the first individual particle beam passes, the double seal-off and column separation module being spatially separable into a first partial module and into a second partial module when the multi-beam particle microscope is not in operation,
wherein:
the first beam tube portion is adjacent the particle source;
the second beam tube portion is adjacent the beam spliter;
the first partial module comprises a first seal-off element configured to sealingly close off the first beam tube portion when the first and second partial modules are spatially separated from each other;
the second partial module comprises a second seal-off element configured to sealingly close off the second beam tube portion when the first and second partial modules are spatially separated from each other;
the double seal-off and column separation module comprises an access in an intermediate region between the first and second seal-off elements so that:
i) during operation of the multi-beam microscope, the intermediate region is evacuated; and
ii) a vacuum between the first and second seal-off elements is breakable to separate the first and the second partial modules from each other.

2. The multi-beam particle microscope of claim 1, further comprising a replacement module, wherein:
the replacement module comprises the first partial module and a column separation module;
relative to the particle-optical beam path, the first partial module and the column separation modules are above the double seal-off and column separation module, including the particle source; and
the replacement module is replaceable as a whole.

3. The multi-beam particle microscope of claim 1, further comprising the following:
a condenser lens system which is arranged in the particle-optical beam path downstream of the particle source and upstream of the multi-beam generator and through which the charged particles pass,
wherein the double seal-off and column separation module is arranged between the condenser lens system and the multi-beam generator.

4. The multi-beam particle microscope of claim 1, further comprising a condenser lens system in the particle-optical beam path downstream of the particle source and upstream of the multi-beam generator and through which the charged particles pass, wherein:
the condenser lens system comprises first and second condenser lenses; and the double seal-off and column separation module is between the first and the second condenser lens.

5. The multi-beam particle microscope of claim 1, further comprising a field lens system in the particle-optical beam path downstream of the multi-beam generator and upstream of the beam splitter, wherein:
the field lens is configured to have the charged first individual particle beams pass therethrough;
the field lens system comprises a first for example magnetic field lens and a second for example magnetic field lens; and
the double seal-off and column separation module is arranged between the first field lens and the second field lens.

6. The multi-beam particle microscope of claim 1, wherein the double seal-off and column separation module is configured to provide:
a vacuum of 10⁻¹⁰ millibar; and/or
a leakage rate of less than or equal to 10⁻⁹ millibar per liter per second.

7. The multi-beam particle microscope of claim 1, wherein the double seal-off and column separation module comprises an electrically conductive material having a relative permeability of at most 1.005.

8. The multi-beam particle microscope of claim 1, wherein:
the first and/or second seal-off element comprises an element selected from the group consisting of an ultrahigh vacuum slider, a flap valve, and a pendulum valve;
and/or the first and/or second seal-off element is configured to be operated manually, pneumatically or electrically.

9. The multi-beam particle microscope of claim 1, wherein, in the installed state along the optical axis of the multi-beam particle microscope, an overall height of the double seal-off and column separation module is at most 8.0 centimeters.

10. The multi-beam particle microscope of claim 1, wherein the double seal-off and column separation module further comprises a heating element within the double seal-off and column separation module.

11. The multi-beam particle microscope of claim 1, wherein the double seal-off and column separation module further comprises an adjustment piece configured to adjust the replacement module, and the adjustment piece is adjacent the first partial module on the particle source side or integrated in the first partial module on the particle source side.

12. The multi-beam particle microscope of claim 1, wherein:
the particle source comprises a cathode tip, an extractor stop and an anode stop, which are arrangeable flush to one another;
the extractor stop comprises an extractor current meter configured to record a spatially resolved current pattern around the extractor aperture; and/or
the anode stop comprises an anode current meter configured to record a spatially resolved current pattern around the anode aperture.

13. The multi-beam particle microscope of claim 12, further comprising a cathode adjuster configured to set a position of the cathode relative to the extractor stop and/or relative to the anode stop on the basis of the recorded current pattern.

14. The multi-beam particle microscope of claim 1, further comprising an electrically conductive covering element which, relative to the particle-optical beam path, is above the multi-beam generator, wherein the electrically conductive covering element is insertable into the particle-optical beam path to cover the multi-beam generator.

15. The multi-beam particle microscope of claim 14, wherein:
the electrically conductive covering element comprises a metallic cantilever;
the metallic cantilever comprises a through opening having a diameter matched to a beam tube diameter of the beam tube adjacent the through opening;
in a first stop position of the electrically conductive covering, the charged particles pass through the through opening unimpeded;
the metallic cantilever comprises a depression having a diameter matched to the beam tube diameter of the adjacent beam tube; and
in second first stop position of the electrically conductive covering, the charged particles are incident on the depression.

16. The multi-beam particle microscope of claim 15, wherein:
the multi-beam particle microscope further comprises a beam current meter in the depression; and/or
the depression is connected to a beam current meter.

17. A system, comprising:
a multi-beam particle microscope according to claim 2;
a second replacement module; and
a depository comprising a vacuum-tight connector for the at least one further replacement module,
wherein:
relative to the particle-optical beam path, the first partial module and the column separation modules are above the double seal-off and column separation module, including the particle source;
the first replacement module is replaceable as a whole; and
the depository is configured to store an interior of the second replacement module in the depository in a high vacuum when a seal-off element of the second replacement module is open.

18. A method, comprising:
providing multi-beam particle microscope according to claim 2,
closing the first seal-off element and the second seal-off element of the double seal-off and column separation module;
breaking the vacuum in the double seal-off and column separation module in a region between the first seal-off element and the second seal-off element;
spatially separating the double seal-off and column separation module into the first partial module and into the second partial module, thereby separating the first replacement module including the first particle source from the remaining part of the multi-beam particle microscope;
arranging a second replacement module including a second particle source on the remaining part of the multi-beam particle microscope, thereby putting together a second double seal-off and column separation module, wherein the second replacement module is already evacuated and wherein the first seal-off element thereof is closed;
evacuating the second double seal-off and column separation module in the region between its first seal-off element and its second seal-off element; and
opening the first seal-off element of the second double seal-off and column separation module and the second seal-off element of the second double seal-off and column separation module after the evacuation has taken place.

19. A multi-beam particle microscope, comprising:
a first vacuum region comprising a first particle source configured to emit charged particles;
a multi-beam generator configured to generate a first field of a multiplicity of charged first individual particle beams from the charged particles;
a first particle-optical unit having a first particle-optical beam path, the first particle-optical unit configured to image the generated first individual particle beams onto a sample surface in an object plane of the multi-beam particle microscope so that the first individual particle beams are incident on the sample surface at incidence locations to define a second field;
a detection system comprising a multiplicity of detection regions configured to define a third field;
a second particle-optical unit with a second particle-optical beam path, the second particle-optical unit configured to image second individual particle beams emanating from the incidence locations in the second field onto the third field;
a magnetic and/or electrostatic objective lens configured to have the first and the second individual particle beams pass therethrough;
a beam splitter in the first particle-optical beam path between the multi-beam generator and the objective lens, the beam splitter in the second particle-optical beam path between the objective lens and the detection system;
a second vacuum region comprising a storage unit which comprises a replacement particle source; and
a transfer mechanism configured to vacuum transfer of the second particle source from the storage unit into an operational position in the first vacuum region.

20. A multi-beam particle microscope, comprising:
a plurality of particle sources arranged fixedly in space, each particle source configured to emit charged particles;
a switching mechanism configured to switch between the particle sources so that at a given time exactly one of the particle sources is an active particle source which emits charged particles;
an electric and/or magnetic deflection mechanism configured to deflect the charged particles emitted by the active particle source onto the optical axis of the multi-beam particle microscope;
a multi-beam generator configured to generate a first field of a multiplicity of charged first individual particle beams from the charged particles from a particle source;
a first particle-optical unit having a first particle-optical beam path, the first particle-optical unit configured to image the generated first individual particle beams onto a sample surface in the object plane so that the first individual particle beams are incident on the sample surface at incidence locations to define a second field;
a detection system with a multiplicity of detection regions configured to define a third field;
a second particle-optical unit having a second particle-optical beam path, the second particle-optical unit configured to image second individual particle beams emanating from the incidence locations in the second field onto the third field;
a magnetic and/or electrostatic objective lens configured to have the first and the second individual particle beams pass therethrough; and
a beam splitter in the first particle-optical beam path between the multi-beam generator and the objective lens, the beam splitter in the second particle-optical beam path between the objective lens and the detection system.
